(19) United States
(12) Patent Application Publication
(10) Pub. No.: US 2023/0209772 A1
(43) Pub. Date: Jun. 29, 2023

(54) METHODS AND APPARATUS FOR RESOURCE LIFETIME AWARE COOLING SYSTEMS

(71) Applicant: Intel Corporation, Santa Clara, CA (US)

(72) Inventors: Francesc Guim Bernat, Barcelona (ES); Arun Hodigere, Bangalore (IN); Kshitij Arun Doshi, Tempe, AZ (US); Henning Schroeder, Karlsruhe (DE); John J. Browne, Limerick (IE)

(21) Appl. No.: 18/145,670

(22) Filed: Dec. 22, 2022

(51) Int. Cl. H05K 7/20; G06F 1/20; G06F 9/48; G06F 9/50

(52) U.S. Cl. CPC H05K 7/20281; G06F 1/20; G06F 9/4893; G06F 9/5094

(57) ABSTRACT

Methods and apparatus for resource lifetime aware cooling schemes are disclosed. A disclosed example apparatus to manage a computing system includes at least one memory, machine readable instructions, and processor circuitry. The processor circuitry is to at least one of instantiate or execute the machine readable instructions to determine an effective age of a computing resource of the computing system, the computing resource associated with a degree of cooling thereof, determine a remaining life of the computing resource, compare the remaining life to a reliability threshold, and adjust at least one of a utilization or the degree of cooling of the computing resource in response to the remaining life not meeting the reliability threshold to adjust the remaining life to meet or exceed the reliability threshold.

### FIELD OF THE DISCLOSURE

This disclosure relates generally to cooling systems and, more particularly, to methods and apparatus for resource lifetime aware cooling schemes.

### BACKGROUND

Platform and computing systems are composed of different computing resources (e.g. CPU, memory, storage, etc.) that allow services to run thereon and achieve a threshold level of service with a finite amount of available resources (e.g. memory bandwidth, input/output (I/O) bandwidth, core count, power, etc.). The computing resources can be composed of or built with different types of materials that have different properties related to thermal dissipation, consumption, energy efficiency and resiliency, etc. Accordingly, resiliency can be correlated to the operational age of the aforementioned materials. For example, memory, such as double data rate (DDR) memory, can experience a reduced operational age/life when operated at relatively high temperatures.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIGS. 17A and 17B provide an overview of an example process flow in accordance with teachings of this disclosure.

FIG. 18 depicts an example reliability management apparatus that can be implemented in examples disclosed herein.

FIG. 19 is a block diagram of an example reliability analysis system in accordance with teachings of this disclosure.

FIGS. 20-22 are flowcharts representative of example machine readable instructions and/or example operations that may be executed by example processor circuitry to implement the example reliability management apparatus of FIG. 18 and/or the example reliability analysis system of FIG. 19.

FIG. 23 is a block diagram of an example processing platform including processor circuitry structured to execute the example machine readable instructions and/or the example operations of FIGS. 20-22 to implement the example reliability management apparatus of FIG. 18 and/or the example reliability analysis system of FIG. 19.

FIG. 24 is a block diagram of an example implementation of the processor circuitry of FIG. 23.

FIG. 25 is a block diagram of another example implementation of the processor circuitry of FIG. 23.

FIG. 26 is a block diagram of an example software distribution platform (e.g., one or more servers) to distribute software (e.g., software corresponding to the example machine readable instructions of FIGS. 20-22) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not to scale. As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Methods and apparatus for resource lifetime aware cooling schemes are disclosed. Platform and computing systems include different computing resources (e.g. CPU, memory, storage) that allow services to run thereon and achieve a threshold level of service with a finite amount of available resources (e.g. memory bandwidth, input/output (I/O) bandwidth, core count, power, etc.). The computing resources can be composed of or built with different types of materials that have different properties related to thermal dissipation, consumption, energy efficiency and resiliency, etc. Resiliency can be correlated to the operational age of the aforementioned materials. For example, memory (e.g., double data rate (DDR) memory) can experience a reduced operational age/life when operated at relatively high temperatures. Particularly, this prolonged exposure to relatively high temperatures that can reduce its overall lifetime. In other words, running the resources at relatively high temperatures can adversely impact a remaining operational life.

Examples disclosed herein enable effective management of reliability of computing systems, networks, devices, server arrays, clusters and/or nodes utilizing numerous resources to increase an overall reliability thereof. Examples disclosed herein track, analyze, calculate and/or determine an overall usage (e.g., an elapsed usage), age (e.g., an operational age) or elapsed life of a computing resource and/or device with tracked usage data and/or telemetry data. As a result, an effective age (e.g., a degree of aging based on utilization/usage) of the computing resource can be determined. According to examples disclosed herein, the effective age corresponds to a utilization of the computing resource over time (e.g., based on current usage over time, computations over time, time of operation in ambient temperatures, etc.). In turn, a remaining life (e.g., operations to fault, time to fault, current applied to fault, a calculated remaining life of operation, etc.) is determined and/or calculated to characterize a projected time before a fault, failure and/or malfunction is encountered. Accordingly, the remaining life or another parameter associated therewith can be compared to a reliability threshold, which can be related to a time to scheduled maintenance/service interval. According to examples disclosed herein, a degree of cooling of the computing resource is adjusted in response to the aforementioned remaining life not meeting the reliability threshold so that the remaining life can be adjusted to meet or exceed the reliability threshold. The degree of cooling can be controlled by adjusting utilization (e.g., workloads, clock speeds, throughput, etc.) or by controlling provided cooling (e.g., controlling a degree of cooling fluid provided to the computing resource), amongst other methodologies/techniques of controlling cooling (e.g., fan control, powered cooler control, etc.). As a result, an overall reliability of an associated computing/server system can be maintained at a relatively high level with an adjusted degree of cooling and/or utilization. In some examples, the reliability of the system is maintained in conjunction with maintaining performance thereof such that the performance can be based on a service level agreement (SLA) or a specified level of performance.

In some examples, the remaining life of the computing resource is calculated based on a predicted usage (e.g., a predicted computational load over the course of a resource's operational life span). In some such examples, the predicted usage is determined with machine learning by utilizing a long short-term memory (LS™) model, for example. Specifically, the machine learning model may be trained based on inputs such as tracked usage (of the same computing resource) of an individual computing resource or historical data associated with others of the same type of computing resources. The model can output a predicted future usage of the computing resource and/or a relationship of remaining life with usage parameters (e.g., current draw over time). Additionally or alternatively, a degree to which cooling is reduced/increased is to be calculated for a controlled degree of adjusted reliability. In some such examples, the degree is based on equalizing (e.g., within 5%) and/or equating the remaining life of the computing resource with another computing resource.

According to examples disclosed herein, where the aforementioned computing resource is a first computing resource such that cooling is managed between the first computing resource and a second computing resource, an overall usage or elapsed life of the second computing resource and/or device can be determined/tracked. In turn, a remaining life of the second computing resource is determined so that the remaining life of the first computing resource is compared to the second remaining life of the second computing resource. Accordingly, a first degree of cooling of at least one of the first computing resource or the second computing resource is reduced while a second degree of cooling of the other of the first computing resource or the second computing resource is increased. In other words, one of the first and second computing resources is provided with reduced cooling while the other of the first and second computing resources is provided with increased cooling, thereby enabling a greater overall reliability of the combination of the first and second computing resources. As a result, a remaining life of one of the first and second computing devices is reduced to increase the remaining life of the other one of the first and second computing devices, which can be counterintuitive.

Examples disclosed herein can utilize liquid cooling or any other appropriate cooling technology, methodology and/or technique. For example, a cooling controller can control a degree of fluid flow provided to individual computing resources. In other words, cooling fluid can be diverted between ones of the computing resources to increase an overall reliability of a computing system such that computing resources predicted to have a lower remaining life can be provided with increased cooling fluid and, conversely, computing resources predicted to have a higher remaining life (e.g., more remaining life than needed) can be provided with a decreased amount of cooling liquid/fluid.

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, accelerators, artificial intelligence computing, machine learning computing, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic component(s). An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

A liquid cooling system or fluid cooling system can involve at least one of single-phase cooling or two-phase cooling. As used herein, single-phase cooling (e.g., single-phase immersion cooling) means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling (e.g., two-phase immersion cooling) means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, indirect cooling and immersion cooling typically involves at least one cooling liquid (which may or may not change to the vapor phase when in use). Example systems, apparatus, and associated methods to improve cooling systems and/or associated cooling processes are disclosed herein.

As used herein, the term “computing resource” refers to a device, component and/or assembly that is associated with operation and performance of a platform computing system. Accordingly, the term “computing resource” can refer to processing circuitry, memory, storage, etc. As used herein, the terms “age” and “effective age” refer to a degree to which a computing resource has exhibited use or stress, electrical or otherwise, during its operation and, thus, do not necessarily correspond to an operational time of field run-time thereof. As used herein, the term “remaining life” refers to an amount of remaining operational time and/or performance of the computing resource.

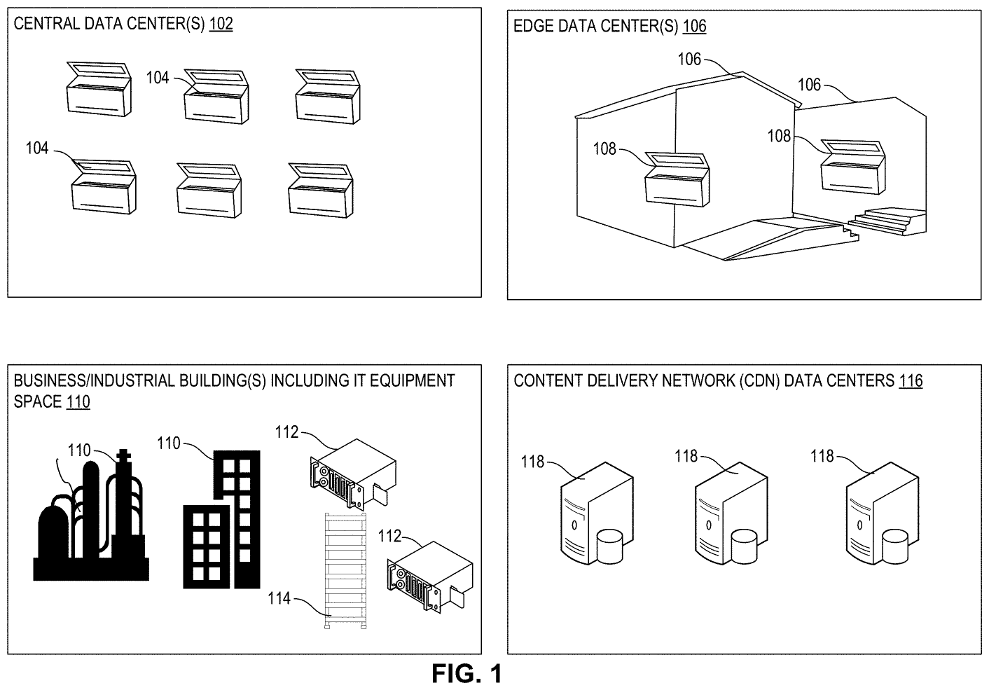

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

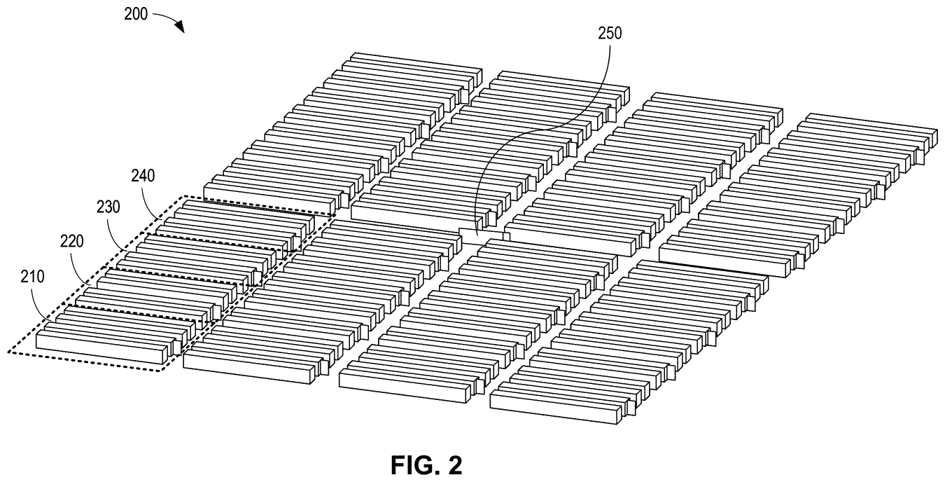

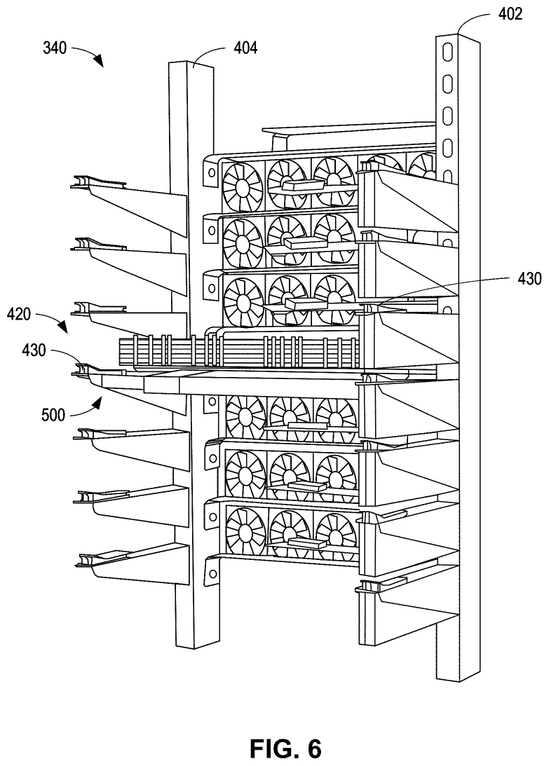

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

In addition to or as an alternative to the immersion tanks 104, 108, any of the example environments of FIG. 1 can utilize one or more liquid cooling systems having a cold plate to control the temperature of the electronic devices/components in the example environments. An example liquid cooling system and example cold plates are disclosed in further detail in connection with FIGS. 1-18.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily computing resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

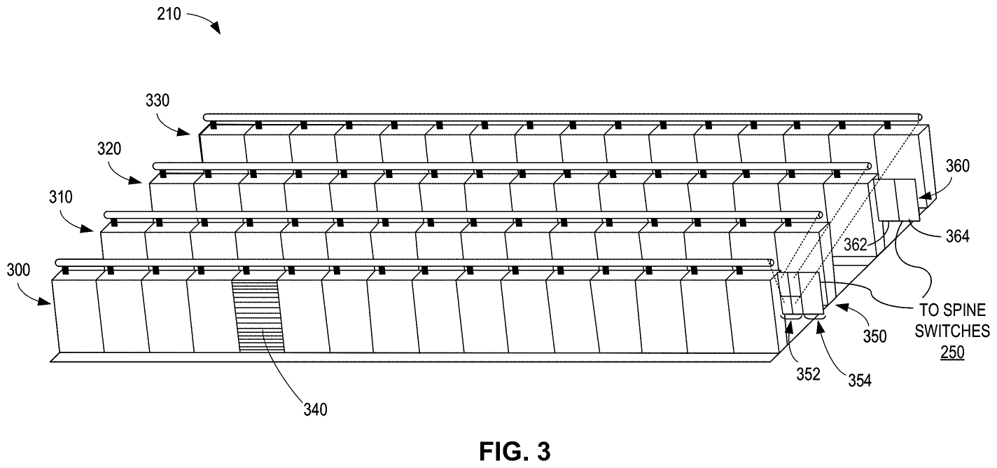

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

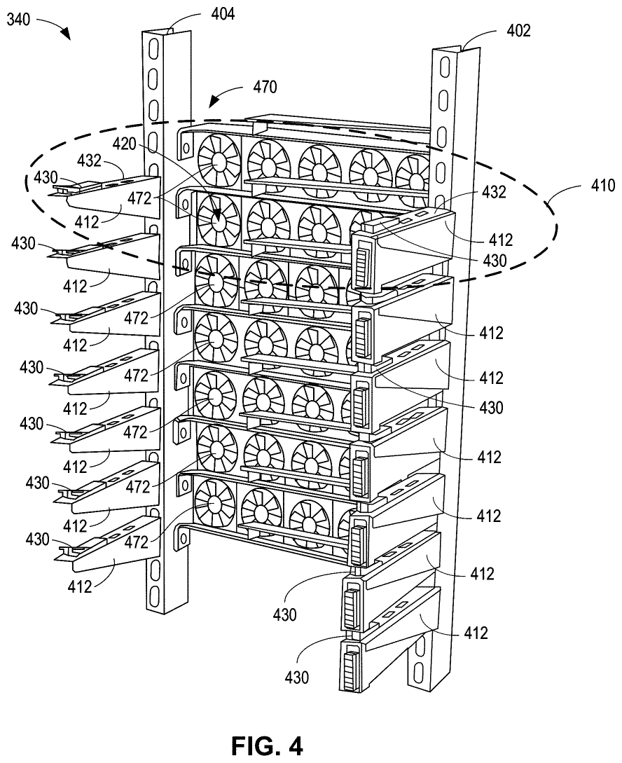

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

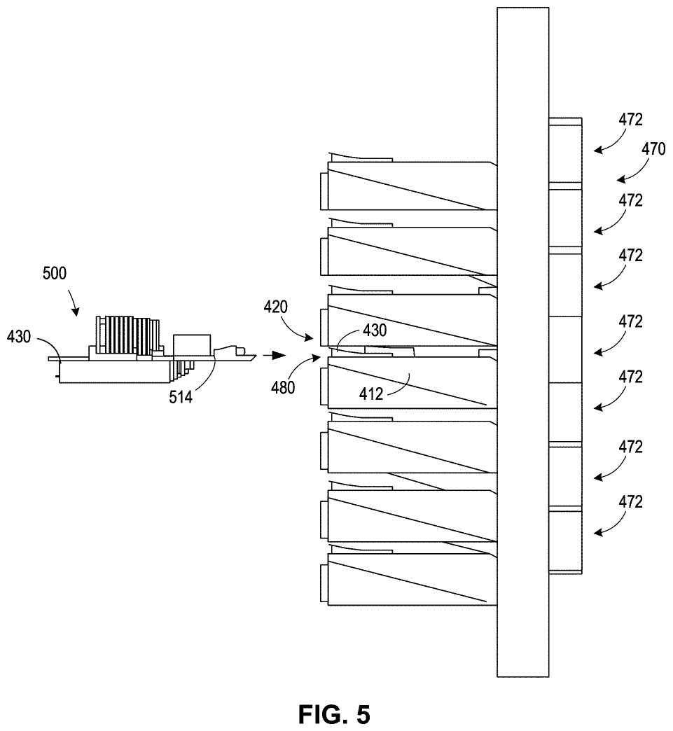

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

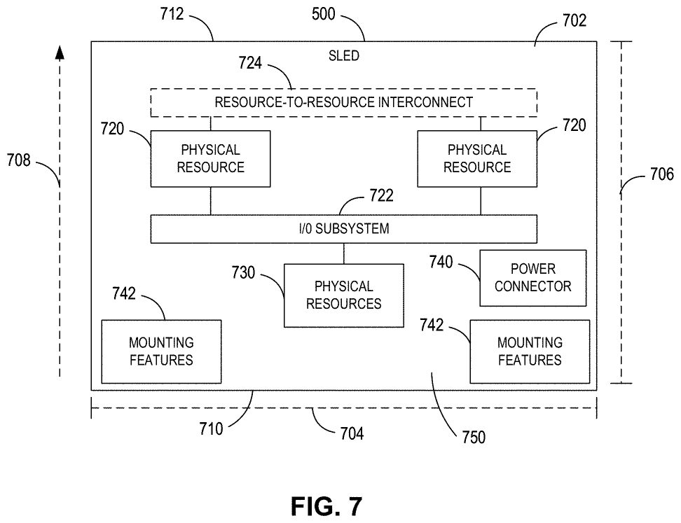

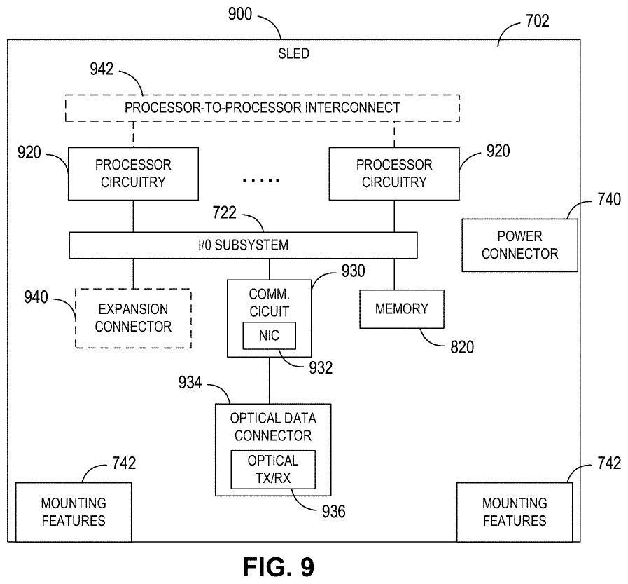

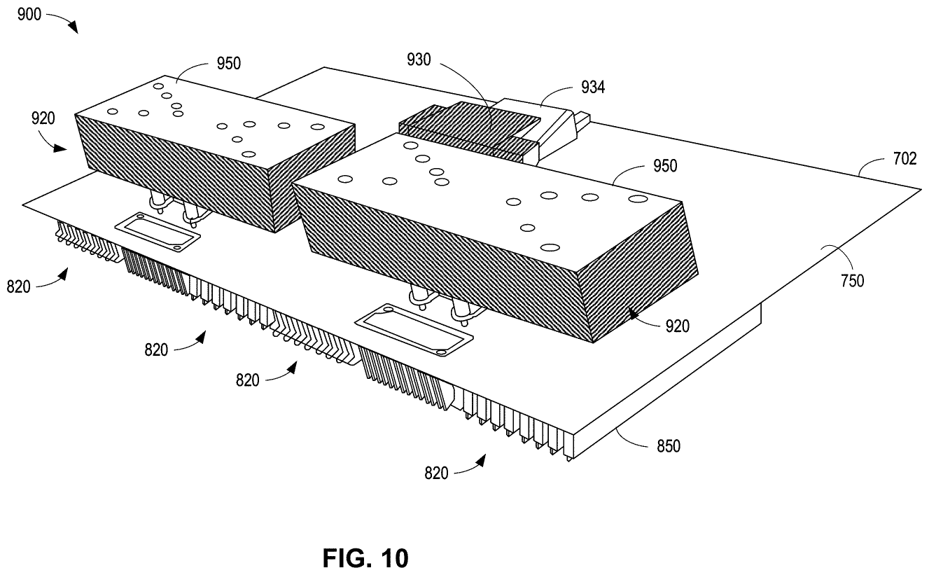

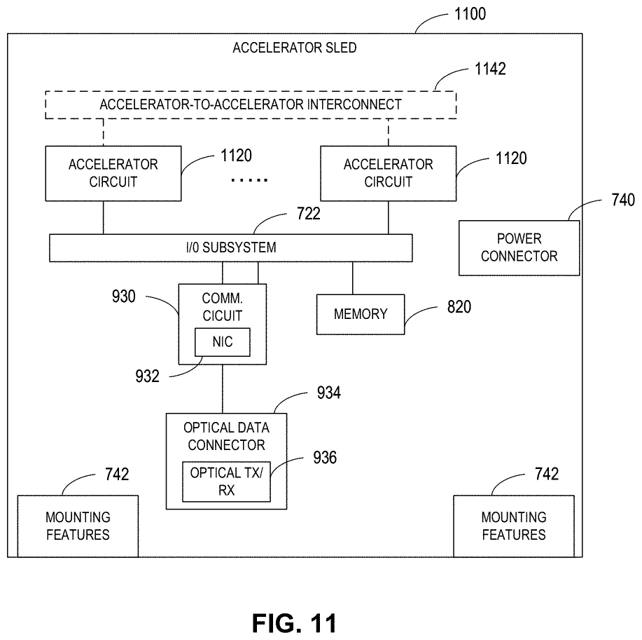

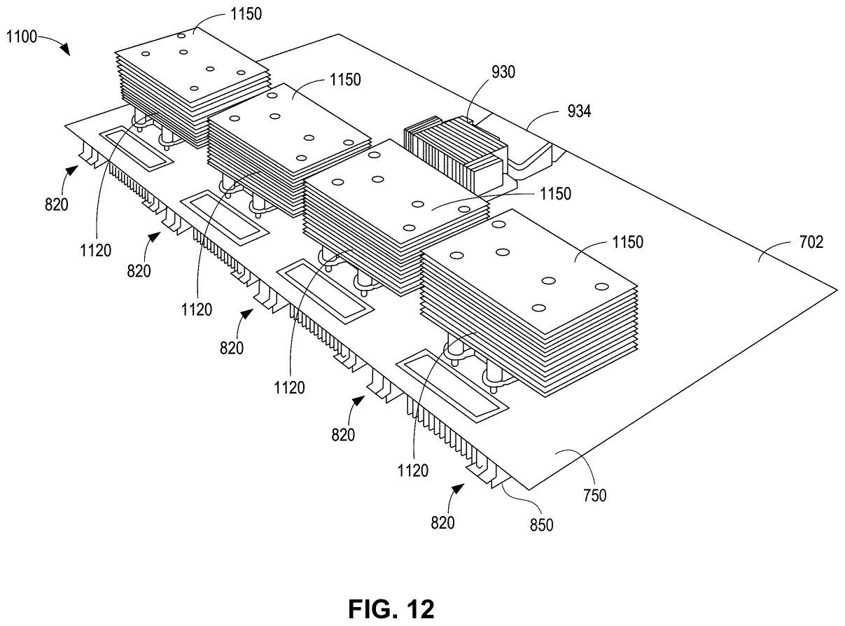

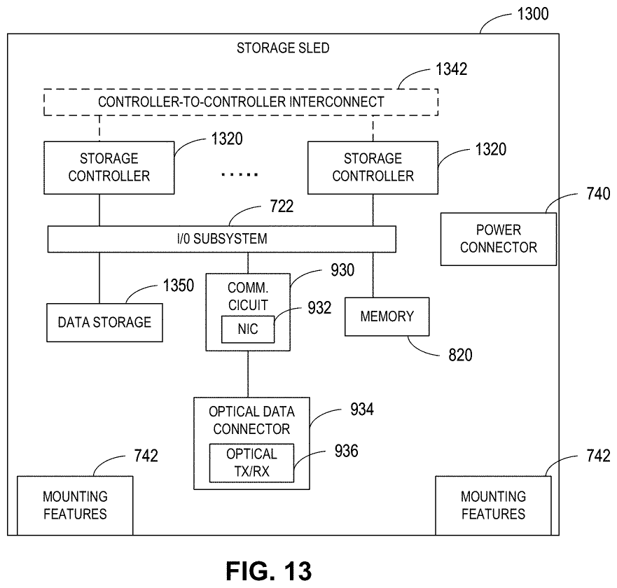

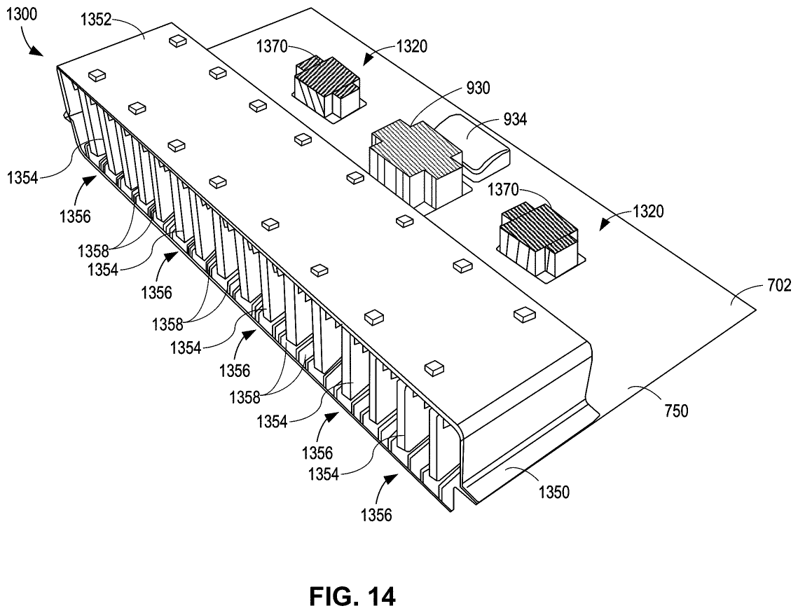

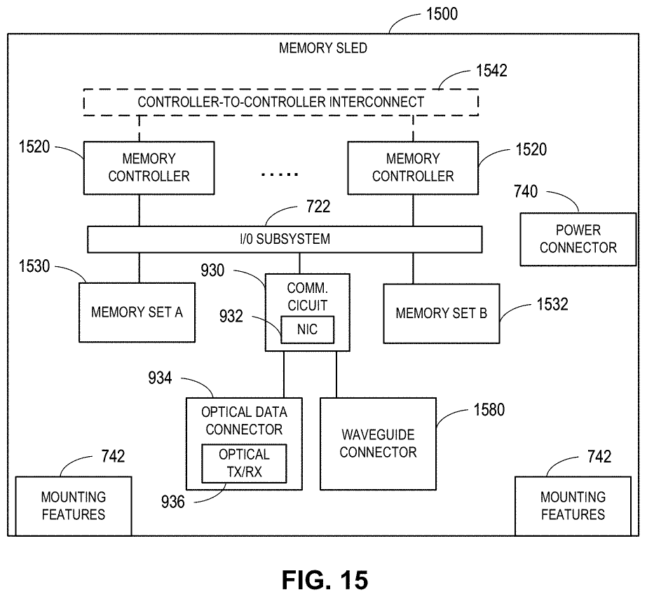

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

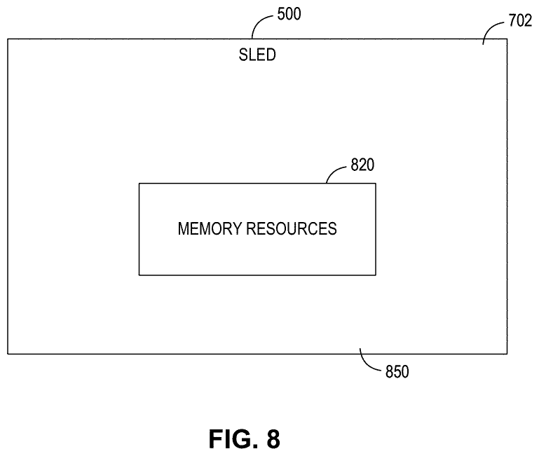

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional computing resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

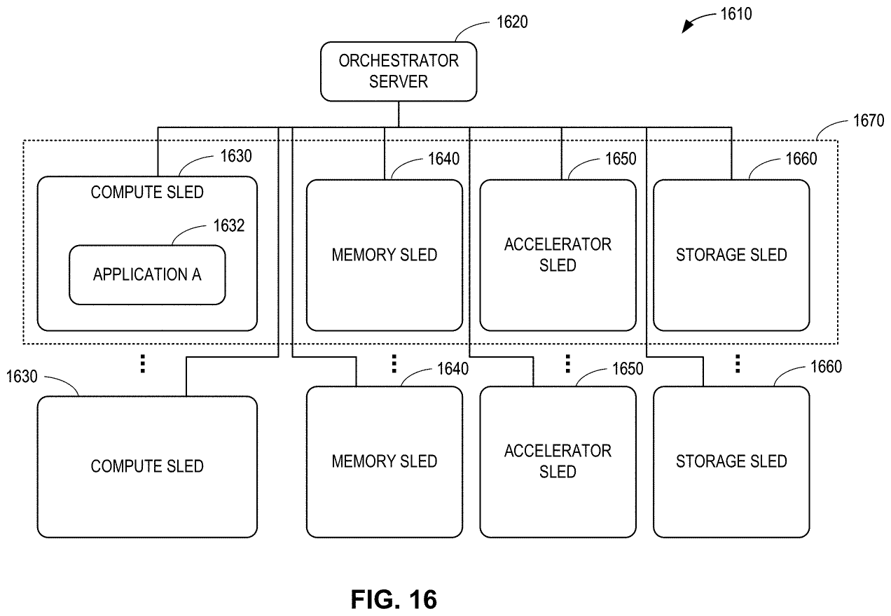

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

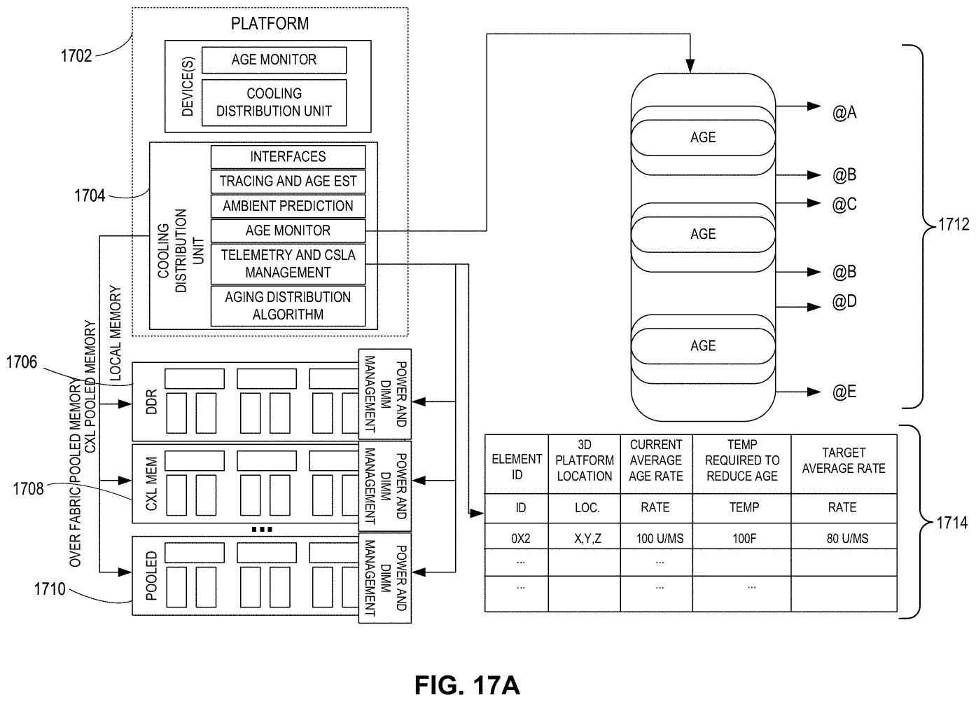

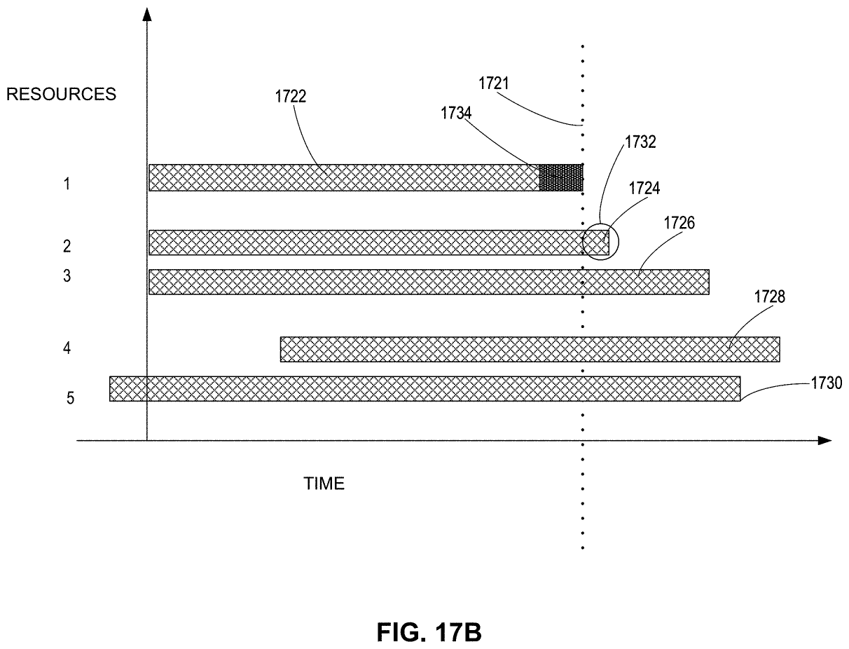

FIGS. 17A and 17B provide an overview of an example process flow in accordance with teachings of this disclosure. In the illustrated example of FIG. 17A, an example control platform 1702, which can be implemented in any of the nodes, processors, servers, sleds (e.g., compute sleds), cooling distribution units (CDUs), server nodes, etc. shown in FIGS. 1-16, is shown. In other words, the control platform 1702 can be implemented within a server/computing system managed thereby or remote from the server/computing system that is controlled by the control platform 1702. The control platform 1702 can be implemented in the orchestration platform 1620. Additionally or alternatively, the example control platform 1702 is distributed amongst numerous computing systems.

In the illustrated example of FIG. 17A, an example CDU 1704, a first computing resource 1706, a second computing resource 1708, and a third computing resource 1710 are depicted. In this example, the first computing resource 1706 corresponds to local memory or random access memory (RAM), while the second computing resource 1708 and the third computing resource correspond to pooled memory, which can be implemented as over fabric pooled memory or compute express link (CXL) pooled memory. The first computing resource 1706, the second computing resource 1708 and/or the third computing resource 1710 can be local or remote to one another (e.g., across different edge/server network nodes, arrays, etc.).

To track and/or estimate an effective age of the first computing resource 1706, the second computing resource 1708 and/or the third computing resource 1710, the example control platform 1702 utilizes an array 1712 with virtual address spaces that can be mapped into different ages that are correlated and/or related to different cooling levels (e.g., cooling setpoints, degrees of cooling, etc.), as well as performance requirements or SLAs associated with the computing resources 1706, 1708, 1710. In this example, the ages and/or usage levels (e.g., historical usage levels) of the corresponding computing resources 1706, 1708, 1710 are tracked and/or measured. Accordingly, a trade-off and/or relationship can be established between usage and/or computing requirements in relation to aging (e.g., expended life) of the computing resources 1706, 1708, 1710. In some examples, a running average of electrical current passing through a computing resource is utilized to determine an electrical stress and/or age thereof. In this example, computing resources are shown as a data array 1714, which corresponds to characterization of computing resources including current performance level, as well as a temperature and/or adjusted utilization (e.g., reduced utilization, re-scheduled utilization, a reduced target performance, etc.) to reduce an age of a computing resource (e.g., to comply with an SLA).

To estimate and/or characterize a relationship between usage, conditions (e.g., temperature conditions, environmental conditions, cooling conditions, etc.) and utilization in relation to age of the first computing resource 1706, the second computing resource 1708 and/or the third computing resource 1710, reliability data (e.g., mean time between failures (MTBF) corresponding to conditions and/or past utilization/usage) can be utilized for characterization of usage and conditions to age. Additionally or alternatively, historical data pertaining to operation and/or usage of the first computing resource 1706, the second computing resource 1708 and/or the third computing resource 1710 can be utilized to estimate and/or characterize parameters (e.g., current draw) with an amount of usage (e.g., computations with the current draw).

To determine a remaining life (e.g., a remaining predicted life) of the first computing resource 1706, the second computing resource 1708 and/or the third computing resource 1710, the control platform 1702 can utilize their respective ages corresponding to the aforementioned past usage in conjunction with an overall specified life thereof (e.g., specified life based on normal operating conditions or expected/predicted operating conditions). For example, the remaining life can be calculated as the difference between an age (e.g., an effective age, an accelerated age) and an expected overall lifetime thereof. The expected overall lifetime can be a standard lifetime (e.g., a lifetime that assumes standard or historical use) or a lifetime that is estimated based on predicted usage and/or past historical usage, for example. In particular examples, the expected overall lifetime can be predicted based on past usage (e.g., past current draws) of the specific individual computing resource.

According to examples disclosed herein, the first computing resource 1706, the second computing resource 1708 and/or the third computing resource 1710 can be tracked to determine an effective age thereof so that their predicted remaining lives can be determined and monitored for potential premature faults and/or failure (that can result in overall system downtime or degraded performance that does not conform to an SLA). To that end, examples disclosed herein utilize the monitored (e.g., in real-time) remaining lives such that cooling (or utilization) can be adjusted to maintain any of the first computing resource 1706, the second computing resource 1708 or the third computing resource 1710 to maintain their remaining life to meet or exceed a reliability threshold, thereby effectively maintaining a reliability of an overall system. In some examples, any one of the resources 1706, 1708, 1710 determined to not meet reliability thresholds triggers an adjustment in cooling/utilization thereof and/or is flagged for service/maintenance.

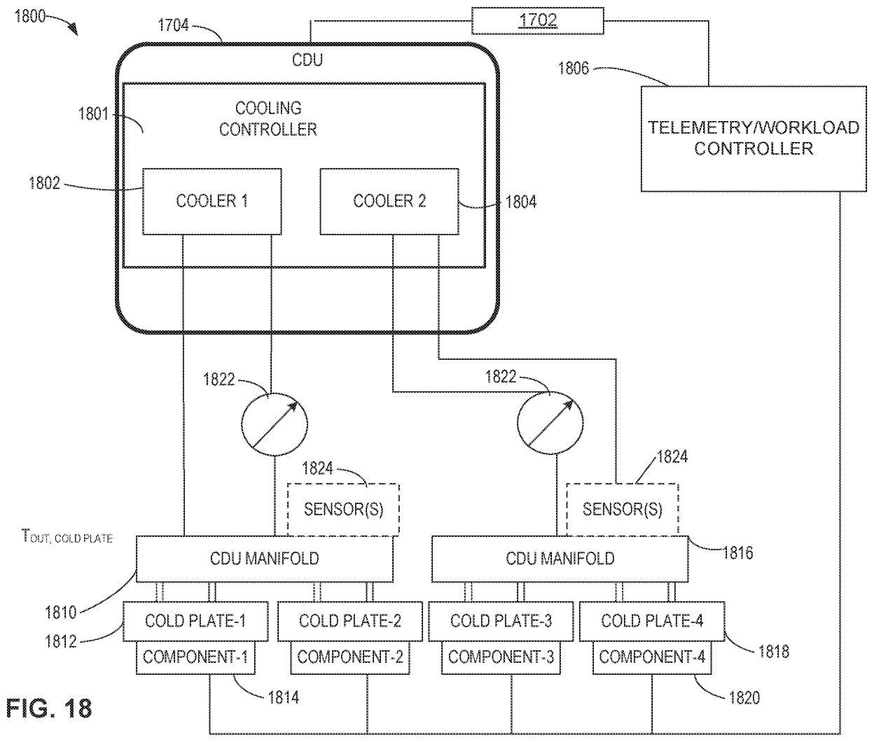

In the illustrated example of FIG. 17A, to adjust a degree of cooling associated with the first computing resource 1706, the second computing resource 1708 and/or the third computing resource 1710, the CDU 1704 can control a degree to which each of the first computing resource 1706, the second computing resource 1708 and the third computing resource 1710 are individually cooled by varying a degree to which cooling fluid is provided to each. In particular, a system of valves, such as described below in connection with FIG. 18, can be controlled to direct the distribution of cooling fluid. Accordingly, at least one of the first computing resource 1706, the second computing resource 1708 and the third computing resource 1710 can be provided with a reduced degree of cooling while another one of the first computing resource 1706, the second computing resource 1708 and the third computing resource 1710 can be provided with an increased degree of cooling. To that end, a computing resource that originally had the potential to fail prematurely can be provided with increased cooling to mitigate any potential premature failure and, thus, increase an overall reliability of the system (even though another resource with a longer predicted remaining life may experience reduced cooling). Accordingly, examples disclosed herein can effectively manage the tradeoff between desired overall performance and system-level reliability. In some examples, separate CDUs can be utilized to cool each of the first computing resource 1706, the second computing resource 1708 and the third computing resource 1710 (e.g., in a distributed system).

In some examples, the cooling is adjusted to the first computing resource 1706, the second computing resource 1708 and/or the third computing resource 1710 to substantially equalize (e.g., within 10%) remaining lifetimes of the first computing resource 1706, the second computing resource 1708 and the third computing resource 1710. In other words, remaining lifetimes can be substantially equated based on cooling and/or utilization (e.g., equated within 10%). As mentioned above, an SLA or other performance requirement can be taken into account when determining a degree of cooling provided to each of the first computing resource 1706, the second computing resource 1708 and the third computing resource 1710. In particular, examples disclosed herein can ensure that the SLA is met even with redirecting and/or rerouting cooling amongst the first computing resource 1706, the second computing resource 1708 and the third computing resource 1710.

In some examples, computing resources, such as the first computing resource 1706, the second computing resource 1708 and the third computing resource 1710, are grouped together in a cooling group or array by which a degree of cooling is controlled with respect to the entire cooling group or array in contrast to individual components and/or heat generating sources. In other words, a degree of cooling can be controlled for groups of computing resources instead of individual computing resources. Accordingly, the ages and remaining lifetimes of the individual computing resources can be aggregated into corresponding groups for purposes of controlling cooling thereof. In some such examples, the groups are structured and/or organized to associate computing resources associated with a specific cooling line (e.g., the cooling applied to all in the group is from the same cooling source, branch and/or line). According to some examples disclosed herein, a degree of cooling of the first computing resource 1706, the second computing resource 1708 and/or the third computing resource 1710 is controlled so that the overall system can meet a threshold prerequisite amount of time needed until a next service or maintenance interval such that replaceable computing resources (e.g., processors, memory, storage, NIC, etc.) can be swapped or repaired to reduce subsequent downtime.

Additionally or alternatively, utilization (e.g., performance utilization, clock speed, memory bandwidth, data throughput, etc.) of the first computing resource 1706, the second computing resource 1708 and/or the third computing resource 1710 is controlled based on remaining lifetimes thereof. In particular, an amount of performance (e.g., memory bandwidth, I/O bandwidth, core count, power, etc.) of the first computing resource 1706, the second computing resource 1708 and/or the third computing resource 1710 is controlled based on maintaining an overall system reliability (e.g., while maintaining an overall level of performance per an SLA). In a specific example, projected decreased reliability of the first computing source 1706 can result in workloads not being assigned thereto or the first computing source being downclocked (e.g., being run lower than the usual clock speed).

The aforementioned reliability threshold can correspond to a period in which a computing resource can continue to function (e.g., with limited remaining time until a fault/failure occurs), but is to be flagged for replacement and/or repair. In other words, the reliability threshold can correspond to a factor of safety or be associated with a margin (e.g., future usage before the computing resource is to fail and/or exhibit faults). In a specific example, the reliability threshold can correspond to a certain number of hours and/or usage before a fault is likely and/or probable to appear (e.g., the threshold corresponds to 10,000 remaining hours of operational time). In other examples, the reliability threshold can correspond to when failure and/or faults of the computing resource are likely (e.g., a discrete threshold). Additionally or alternatively, the reliability threshold can be adjusted or varied based on usage, environmental factors, etc.

FIG. 17B is a bar graph representation of lifetimes of computing resources designated as “1” through “5” with respect to time. In the illustrated example of FIG. 17B, a line 1721 represents a service interval and/or reliability/survivability goal. As can be seen in FIG. 17B, a computing resource lifetime represented by bar 1722 does not reach the line 1721. In other words, this computing resource does not have a sufficient remaining life (e.g., based on an effective age and projected usage) to reach the service interval represented by the line 1721. As a result, an entire computing system may have an unscheduled downtime. In contrast, computing resources (“2”-“5”) have corresponding bars 1724, 1726, 1728, 1730 that extend past the line 1721. According to examples disclosed herein, cooling to the computing resource (“1”) associated with the bar 1722 can be increased and/or its utilization can be decreased so its reliability can be extended, as generally indicated by extended region 1734, thereby enabling the computing resource associated with the bar 1722 to reach the reliability goal and/or threshold and, thus, preventing the unscheduled downtime of the corresponding computing system. In some examples, the computing resource associated with the bar 1724 (or any other computing resource extending past the line 1721) can be provided with reduced cooling to reduce a degree to which it extends past the line 1721, thereby conserving energy and/or cooling, for example.

According to examples disclosed herein, to enable robust maintenance of computing resources, multiple types of roles can be implemented including, but not limited to (i) a reactive role where faults and changes in cooling solution are monitored based on reported reliability conditions, (ii) a predictive role where “wear” and “lifetime” models can be utilized to predict faults/failure such that adjusted cooling and/or utilization can prevent premature faults/failure, and (iii) fault telemetry where a maintenance/service interval can be planned (e.g., for part swap outs) such that a cooling/utilization management system is coordinated therewith.

FIG. 18 depicts an example reliability management apparatus 1800 that can be implemented in examples disclosed herein. The example reliability management apparatus 1800 is controlled by the control platform 1702 and utilizes a liquid/fluid distribution system that can control cooling of individual computing resources or groups of computing resources. In the illustrated example of FIG. 18, the CDU 1704 includes a cooling controller (e.g., means for controlling at least one valve in a fluid cooling system) 1801 that controls coolers 1802, 1804 that may be associated with the aforementioned immersion tank(s) 104 shown in FIG. 1. Further, the reliability management apparatus 1800 includes a workload/utilization controller 1806 to manage computing resource workloads. In this example, the cooler 1802 of the CDU 1704 is fluidly and/or thermally coupled to a CDU manifold 1810 which, in turn, is coupled/attached to cold plates 1812 that are coupled to computing resources (e.g., compute components, compute units, computing units, compute devices, etc.) 1814. Similarly, the cooler 1804 is fluidly and/or thermally coupled to a CDU manifold 1816 which, in turn, is coupled/attached to cold plates 1818 corresponding to computing resources (e.g., compute components, compute units, computing units, computing devices, etc.) 1820. Example valves 1822 control a degree of cooling and/or an amount of cooling fluid/liquid provided to the manifolds 1810, 1816. In some examples, sensor(s) 1824 are implemented to obtain data pertaining to cooling, age and/or operation of the computing resources 1814, 1820. For example, the sensor(s) 1824 can measure a temperature or another parameter, such as current usage, for example, to be utilized in determining an effective age of the computing resources 1814, 1820. The example sensor(s) 1824 can be placed around a chassis and/or appliance to measure parameters such as temperature, pressure, movement, etc. used for estimating aging.

According to examples disclosed herein, to vary a degree of cooling provided to the computing resources 1814 and the computing resources 1820, at least one of the valves 1822 can be operated. In particular, the cooling controller 1801 can direct an amount of cooling fluid/liquid flowing to the cold plates 1812, 1818 by controlling fluid flowing through each of the valves 1822. However, any other appropriate cooling control system and/or methodology can be implemented instead. While the example valves 1822 shown in FIG. 18 are utilized to control groups of computing resources, the valves 1822 can be implemented to control cooling to individual computing resources and/or devices, for example. In other words, while the CDU manifolds 1810 are implemented in this example, alternatively, the cooler(s) 1802 can be fluidly coupled to the cold plates 1812, 1818 (e.g., the cooler(s) 1802 individually control cooling of ones of the computing resources 1814, 1820).

According to examples disclosed herein, the utilization of the computing resources 1814, 1820 can be controlled by adjusting, re-assigning, rescheduling and/or rescaling compute workloads and/or assignments thereof via the telemetry/workload controller 1806. In other words, at least one of the computing resources 1814, 1820 can be assigned reduced computational workloads to increase cooling and, in turn, its reliability.

While the example of FIG. 18 is shown in the context of utilizing the CDU 1704, examples disclosed herein can, alternatively, be implemented in conjunction with an immersion tank system utilizing the example immersion tank(s) 104 shown in FIG. 1. In particular, the CDU 1704 can be implemented in conjunction with the immersion tank(s) 104, for example. Any appropriate cooling system and/or methodology can be implemented instead.

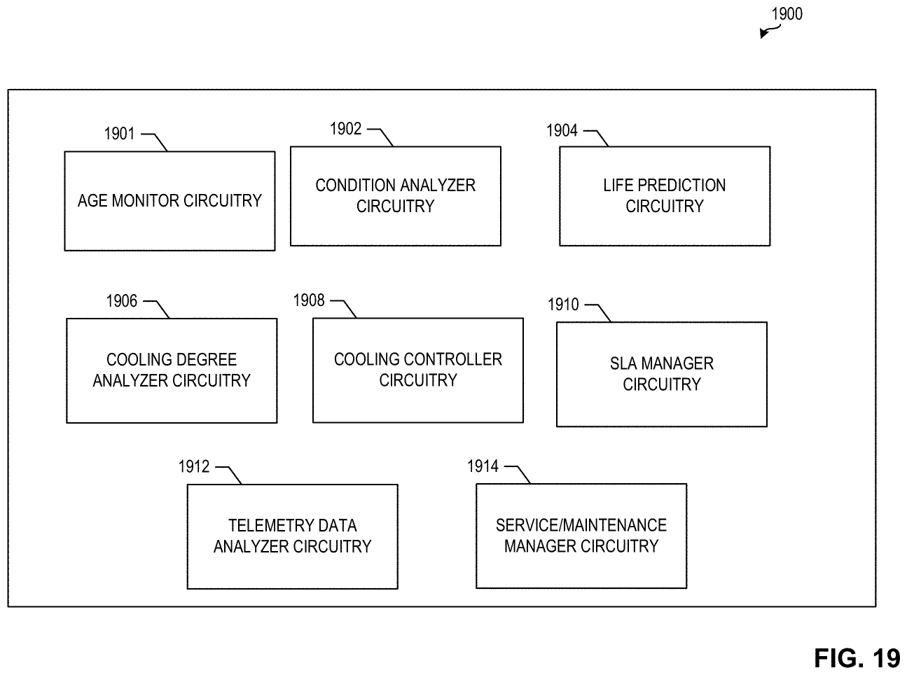

FIG. 19 is a block diagram of an example reliability analysis system 1900 to control and/or manage cooling of different computing resources to increase overall reliability of an overall computing system and/or network. The example reliability analysis system 1900 can be implemented by the control platform 1702, the CDU 1704, the telemetry/workload controller 1806 and/or the cooling controller 1801 shown in FIGS. 17A and 18. Additionally or alternatively, the reliability analysis system 1900 can be implemented in any of the examples disclosed in FIGS. 1-16 (e.g., remote or in-system management). The example reliability analysis system 1900 of FIG. 19 may be instantiated (e.g., creating an instance of, bring into being for any length of time, materialize, implement, etc.) by processor circuitry such as a central processing unit executing instructions. Additionally or alternatively, the reliability analysis system 1900 of FIG. 19 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 19 may, thus, be instantiated at the same or different times. Some or all of the circuitry may be instantiated, for example, in one or more threads executing concurrently on hardware and/or in series on hardware. Moreover, in some examples, some or all of the circuitry of FIG. 19 may be implemented by microprocessor circuitry executing instructions to implement one or more virtual machines and/or containers.

The example reliability analysis system 1900 includes example age monitor circuitry (e.g., means for determining an effective age) 1901, example condition analyzer circuitry 1902, example life prediction circuitry (e.g., means for determining a remaining life) 1904, example cooling degree analyzer circuitry (e.g., means for comparing the remaining life to a reliability threshold, means for determining the adjusted degree of cooling) 1906, example cooling controller circuitry (e.g., means for adjusting at least one of a utilization or the degree of cooling) 1908, SLA manager circuitry 1910, example telemetry data analyzer circuitry 1912 and example service/maintenance manager circuitry 1914. According to examples disclosed herein, the reliability analysis system 1900 can be part of or communicatively coupled to the CDU 1704 for liquid cooling control. However, any appropriate controllable cooling scheme that enables cooling control over different computing resources/computing resource groups can be implemented instead such as, but not limited to, differential fan control (e.g., controlling different cooling fans associated with different respective resources with different degrees of cooling), control of clock speed, control of powered coolers like Peltier coolers, ambient cooling control, etc.

The example age monitor circuitry 1901 is implemented to determine, track, aggregate, record (over time), operational usage and/or an effective age of a computing resource (e.g., a computing component, a compute element, etc.). According to the examples disclosed herein, the effective age can be expressed as an expended/used operational life of the computing resource. This expended/used operational life can be based on power draw over time, current passage over time, computational usage history, memory utilization, bandwidth data, average temperature history, time in the field, operating conditions (e.g., ambient temperature over time, airflow history, etc.).

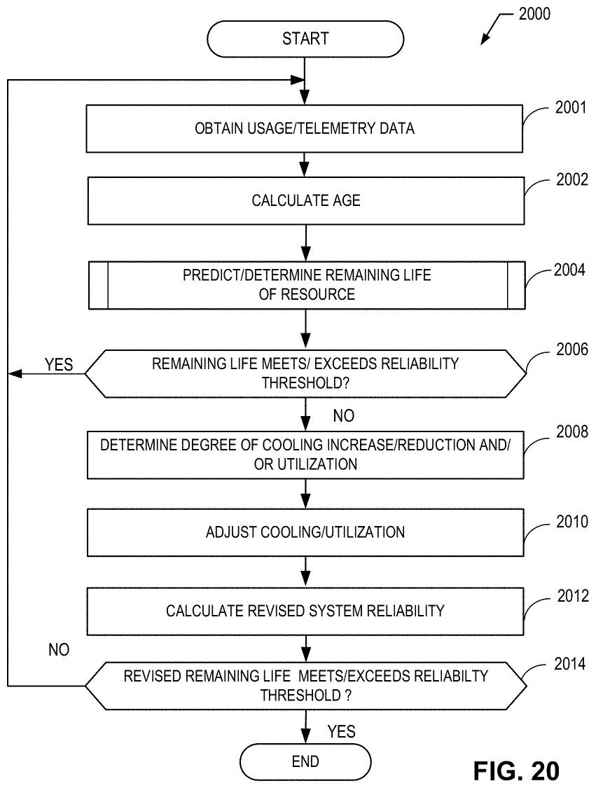

In some examples, the age monitor circuitry 1901 monitors for computing resources that are experiencing higher/increased aging than baseline aging (e.g., aging under typical operation conditions, aging set forth in a computing resource specification, etc.). In turn, with respect to these computing resources, workloads associated with the aging as well as their contributions to aging are identified. Accordingly, based on priorities of the workloads, throttling schemes can be implemented for the workloads (e.g., changing P-states for different workloads). Additionally or alternatively, cooling provided/routed to the computing resources can be adjusted to increase the remaining life such that a reliability threshold is met. According to examples disclosed herein, the age monitor circuitry 1901 can maintain a distribution of aging of computing resources. In some examples, the age monitor circuitry 1901 is instantiated by processor circuitry executing age monitor instructions and/or configured to perform operations such as those represented by the flowcharts of FIGS. 20-22.

The example condition analyzer circuitry 1902 determines and/or analyzes conditions associated with the computing resource. For example, the condition analyzer circuitry 1902 can determine ambient temperatures experienced over time (e.g., over a time history) by the computing resource (e.g., a temperature history of the computing resource). Additionally or alternatively, the condition analyzer circuitry 1902 determines and/or characterizes power/current draw, air flow, cooling uptime, etc. of the computing resource. According to examples disclosed herein, the condition analyzer circuitry 1902 can be utilized to monitor for faults and changes in cooling, thereby enabling adjustment of cooling/utilization of the computing resource. In some examples, the condition analyzer circuitry 1902 is instantiated by processor circuitry executing condition analyzer instructions and/or configured to perform operations such as those represented by the flowcharts of FIGS. 20-22.

The life prediction circuitry 1904 of the illustrated example calculates a remaining life of the computing resource. For example, the life prediction circuitry 1904 determines the remaining life of the computing resource based on the aforementioned usage such that the previous usage is presumed for the remaining operation of the computing resource. Additionally or alternatively, the remaining life of the computing resource is calculated by the life prediction circuitry 1904 based on predicted usage and/or utilization of the computing resource. In particular, the example life prediction circuitry 1904 can predict usage and/or utilization of the computing resource based on prior usage/utilization or utilization via a trained machine learning model to predict upcoming/future usage/utilization.

In some examples, the life prediction circuitry 1904 utilizes “wear and tear” models to predict faults of the computing resources. Additionally or alternatively, fault telemetry can be implemented by the life prediction circuitry 1904, such as dual in-line memory module (DIMM) memory logs for example, to predict faults for cooling and/or utilization adaptation. In other words, examples disclosed herein can utilize logs associated with hardware for fault prediction. In some examples, the life prediction circuitry 1904 is instantiated by processor circuitry executing life prediction instructions and/or configured to perform operations such as those represented by the flowcharts of FIGS. 20-22.

According to the illustrated example of FIG. 19, the cooling degree analyzer circuitry 1906 calculates and/or determines a degree of cooling and/or utilization to be adjusted for at least one computing resource. For example, the cooling degree analyzer circuitry 1906 increases cooling to a single computing resource that is deemed to have a relatively premature failure based on effective age. In another example, the cooling degree analyzer circuitry 1906 can determine that a first computing resource with a first remaining life is to be applied with reduced cooling while a second computing resource with a second remaining life less than the first remaining life is to be applied with increased cooling, thereby conserving energy that would cool the first computing resource to a reliability level that is not necessitated. In some such examples, the degree of cooling applied to and/or utilization of the first and second computing resources can be adjusted based on substantially equating (e.g., within 10%) predicted remaining lives of the first and second computing resources.

Additionally or alternatively, different phases are utilized by the cooling degree analyzer circuitry 1906 to control cooling to different components. For example, in a storage phase, computing resources such as storage devices might be cooled to a greater degree while in a compute phase, computing resources such as processors and/or memory are cooled to a greater degree. In some examples, the cooling degree analyzer circuitry 1906 is instantiated by processor circuitry executing cooling degree analyzer instructions and/or configured to perform operations such as those represented by the flowcharts of FIGS. 20-22.

The example cooling controller circuitry 1908 controls a degree of cooling provided and/or utilization assigned to at least one computing resource. According to examples disclosed herein, the degree of cooling and/or utilization can be adjusted and/or controlled by the cooling controller circuitry 1908 so that an overall system has an increased predicted reliability. In particular, the example cooling controller circuitry 1908 of the illustrated example can utilize and/or control the CDU 1704 to vary and/or adjust cooling individually applied to ones of the computing resources. Additionally or alternatively, the cooling controller circuitry 1908 controls utilization of at least one computing resource to maintain a desired overall reliability. In some examples, the cooling controller circuitry 1908 is instantiated by processor circuitry executing cooling controller instructions and/or configured to perform operations such as those represented by the flowcharts of FIGS. 20-22.

In some examples, the SLA manager circuitry 1910 is implemented to ensure that an overall system is meeting requirements corresponding to an SLA or other performance requirement. The SLA manager circuitry 1910 can monitor a platform and service level objectives and work in conjunction with the age monitor circuitry 1901 to ensure that SLAs are complied with while working to increase an overall system reliability. In some examples, the SLA manager circuitry 1910 is instantiated by processor circuitry executing SLA manager instructions and/or configured to perform operations such as those represented by the flowcharts of FIGS. 20-22.

In the illustrated example, the telemetry data analyzer circuitry 1912 is implemented to analyze telemetry data associated with at least one computing resource. The telemetry data can correspond to fault telemetry or external telemetry (e.g., ambient temperatures experienced by components and/or nodes of a server system). In some examples, the telemetry data analyzer circuitry 1912 is instantiated by processor circuitry executing telemetry data analyzer instructions and/or configured to perform operations such as those represented by the flowcharts of FIGS. 20-22.

The example service/maintenance manager 1914 can be implemented to determine whether at least one computing resource may experience a fault or other failure prior to an upcoming service/maintenance interval. Additionally or alternatively, the service/maintenance manager circuitry 1914 is utilized to identify a computing resource that is predicted to not have a sufficient remaining lifetime until the next service/maintenance interval. As a result, the computing resource can be designated by the service/maintenance manager circuitry 1914 for early repair and/or replacement. Additionally or alternatively, the service/maintenance manager circuitry 1914 calculates and/or determines a next service/maintenance interval (e.g., based on the computing resource with the lowest predicted remaining life). In some examples, the service/maintenance manager circuitry 1914 is instantiated by processor circuitry executing service/maintenance manager instructions and/or configured to perform operations such as those represented by the flowcharts of FIGS. 20-22.

While an example manner of implementing the reliability analysis system 1900 of FIG. 19 is illustrated in FIG. 19, one or more of the elements, processes, and/or devices illustrated in FIG. 19 may be combined, divided, re-arranged, omitted, eliminated, and/or implemented in any other way. Further, the example age monitor circuitry 1901, the example condition analyzer circuitry 1902, the example life prediction circuitry 1904, the example cooling degree analyzer circuitry 1906, the example cooling controller circuitry 1908, the example SLA manager circuitry 1910, the example telemetry data analyzer circuitry 1912 and the example service/maintenance manager circuitry 1914, and/or, more generally, the example reliability analysis system 1900 of FIG. 19, may be implemented by hardware alone or by hardware in combination with software and/or firmware. Thus, for example, any of the example age monitor circuitry 1901, the example condition analyzer circuitry 1902, the example life prediction circuitry 1904, the example cooling degree analyzer circuitry 1906, the example cooling controller circuitry 1908, the example SLA manager circuitry 1910, the example telemetry data analyzer circuitry 1912 and the example service/maintenance manager circuitry 1914, and/or, more generally, the example reliability analysis system 1900, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example reliability analysis system 1900 of FIG. 19 may include one or more elements, processes, and/or devices in addition to, or instead of, those illustrated in FIG. 19, and/or may include more than one of any or all of the illustrated elements, processes and devices.

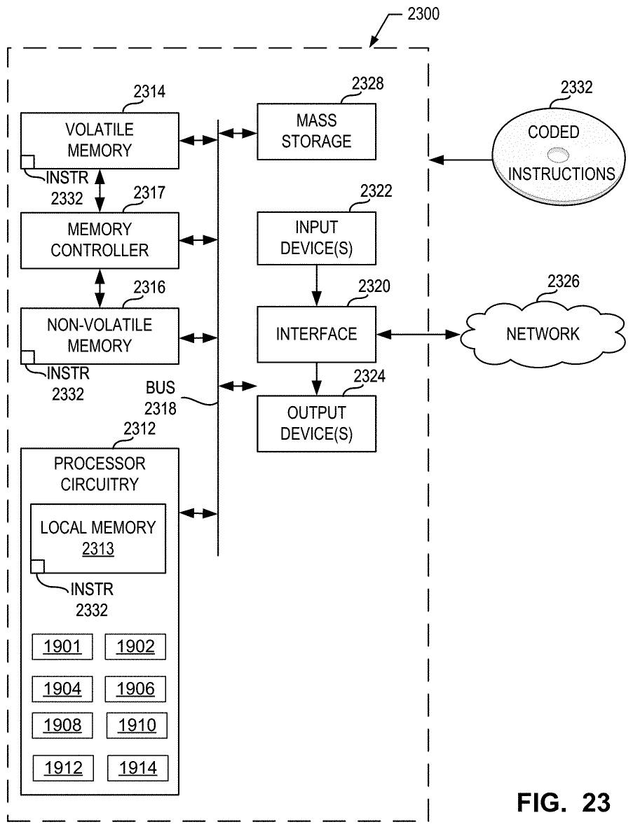

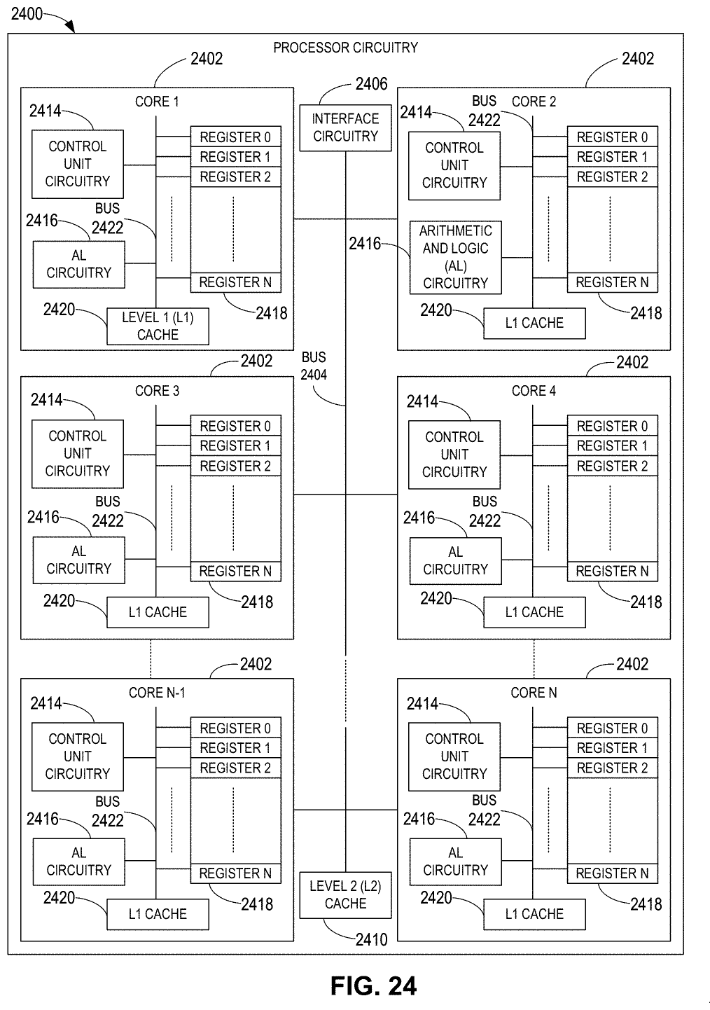

Flowcharts representative of example machine readable instructions, which may be executed to configure processor circuitry to implement the reliability analysis system 1900 of FIG. 19, are shown in FIGS. 20-22. The machine readable instructions may be one or more executable programs or portion(s) of an executable program for execution by processor circuitry, such as the processor circuitry 2312 shown in the example processor platform 2300 discussed below in connection with FIG. 23 and/or the example processor circuitry discussed below in connection with FIGS. 24 and/or 25. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 20-22, many other methods of implementing the example reliability analysis system 1900 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 20-22 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 20 is a flowchart representative of example machine readable instructions and/or example operations 2000 that may be executed and/or instantiated by processor circuitry to control and/or manage cooling of computing resources to maintain an overall reliability of a computing system, for example. The machine readable instructions and/or the operations 2000 of FIG. 20 begin at block 2001, at which the telemetry data analyzer circuitry 1912 obtains and/or collects telemetry data and/or usage data associated with computing resources of a computing platform, such as the data centers 102 and/or the server(s) 112 shown in FIG. 1.

In this example, at block 2002, the example age monitor circuitry 1901 calculates, estimates and/or determines an effective age and/or operational use of a computing resource. The example age monitor circuitry 1901 can make the determination based on the aforementioned telemetry and/or usage data.

At block 2004, the life prediction circuitry 1904 and/or the condition analyzer circuitry 1902 of the illustrated example predicts and/or determines a remaining life of the computing resource. The prediction may be based on past usage/utilized (e.g., current consumption per time average, historical data, anticipated future conditions, etc.).

At block 2006, the example cooling degree analyzer circuitry 1906 determines whether the remaining life of the computing resource and/or data associated therewith exceeds or meets a reliability threshold (e.g., a threshold predicted remaining life, scheduled time to service/maintenance, etc.). If the remaining life of the computing resource and/or data associated therewith exceeds or meets the reliability threshold (block 2006), control of the process returns to block 2001. Otherwise, the process proceeds to block 2008.

At block 2008, the example cooling degree analyzer circuitry 1906 determines a degree to which cooling and/or utilization of the computing resource is to be adjusted. In some examples, the degree to which the cooling and/or utilization of the computing resource is to be adjusted is based on a predicted remaining life of the computing resource meeting or being equal to the reliability threshold.

In the illustrated example of FIG. 20, at block 2010, the cooling controller circuitry 1908 adjusts cooling to and/or utilization of the computing resource. In this example, the cooling controller circuitry 1908 controls the CDU 1704 of FIG. 17A and/or the valves 1822 of FIG. 18 to control a degree to which the computing resource is cooled, for example.

At block 2012, the life prediction circuitry 1904 determines if the revised overall system reliability exceeds the aforementioned threshold reliability. For example, the life prediction circuitry 1904 can compare an estimated remaining life of the computing resource to an estimated time to a service/maintenance interval and if the remaining life exceeds the estimated time to the service maintenance interval, the revised overall system reliability exceeds the aforementioned threshold reliability.

At block 2014, if the life prediction circuitry 1904 has determined that the revised overall system reliability meets the threshold reliability (block 2012), the process ends. Otherwise, control of the process returns to block 2001.

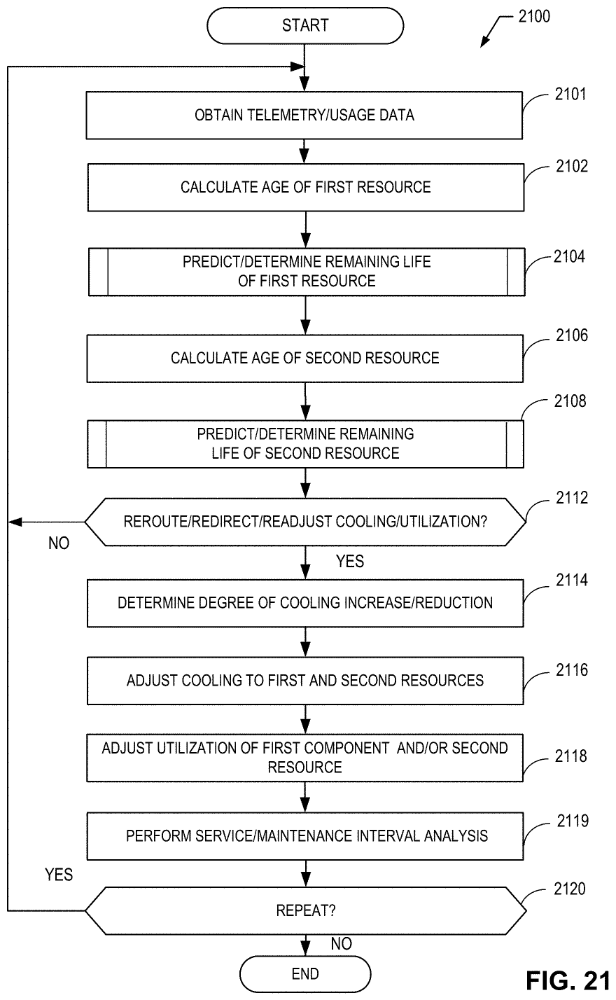

FIG. 21 is a flowchart representative of example machine readable instructions and/or example operations 2100 that may be executed and/or instantiated by processor circuitry to control and/or manage provided cooling to multiple computing resources of a computing system. The machine readable instructions and/or the operations 2100 of FIG. 21 begin at block 2101, at which the telemetry data analyzer circuitry 1912 obtains and/or collects telemetry and/or usage data associated with computing resources of a computing platform, such as the data centers 102 and/or the server(s) 112 of FIG. 1.

In the illustrated example of FIG. 21, at block 2102, the example age monitor circuitry 1901 calculates, estimates and/or determines an effective age and/or operational use of a first computing resource of the computing resources.

At block 2104, the life prediction circuitry 1904 and/or the condition analyzer circuitry 1902 of the illustrated example predicts and/or determines a remaining life of the first computing resource.

At block 2106, the example age monitor circuitry 1901 calculates, estimates and/or determines an age and/or operational use of a second computing resource of the computing resources.

At block 2108, the life prediction circuitry 1904 and/or the condition analyzer circuitry 1902 of the illustrated example predicts and/or determines a remaining life of the second computing resource.

At block 2112, the example cooling degree analyzer circuitry 1906 determines whether cooling to and/or utilization of at least one of the first or second computing resources is to be rerouted, readjusted and/or redirected. In other words, the cooling degree analyzer circuitry 1906 determines whether a degree of cooling is to be adjusted for at least one of the first or second computing resources. If the cooling is not to be rerouted/redirected (block 2112), control of the process returns to block 2101. Otherwise, the process proceeds to block 2114.

At block 2114, the example cooling degree analyzer circuitry 1906 determines a degree to which cooling of at least one of the first or second computing resources is to be rerouted and/or redirected. In other words, the cooling degree analyzer circuitry 1906 determines an adjustment to cooling of the first and second computing resources.

In the illustrated example of FIG. 21, at block 2116, the cooling controller circuitry 1908 adjusts cooling provided to and/or distributed between the first and second computing resources. In this example, the cooling controller circuitry 1908 controls the CDU 1704 of FIG. 17A and/or the valves 1822 of FIG. 18 to control a degree to which the first and second computing resources are each cooled, for example.

At block 2118, in some examples, the cooling controller circuitry 1908 adjusts utilization (e.g., computing utilization, throughput, calculations/time, core usage count, etc.) of the first computing resource and/or the second computing resource. For example, the cooling controller circuitry 1908 can reduce a utilization of the first computing resource if the first computing resource is predicted to have less remaining life than the second computing resource. In such examples, the cooling controller circuitry 1908 can increase a utilization of the second computing resource (e.g., to fulfill performance/SLA requirements).

At block 2119, the service/maintenance manager circuitry 1914 of the illustrated example performs a service/maintenance interval analysis. The analysis can be associated with ensuring that the first and second computing resources have a predicted remaining life that lasts until an upcoming service maintenance interval. In some examples, the service/maintenance manager circuitry 1914 determines a next service/maintenance interval (e.g., a next service/maintenance interval in three months).

At block 2120, it is determined by the example life prediction circuitry 1904 whether to repeat the process. If the process is to be repeated (block 2120), control of the process returns to block 2101. Otherwise, the process ends. This determination may be based on an overall system reliability and/or predicted remaining life not meeting or exceeding a threshold level of reliability and/or predicted remaining life. Additionally or alternatively, the determination may be based on whether further monitoring is necessitated.

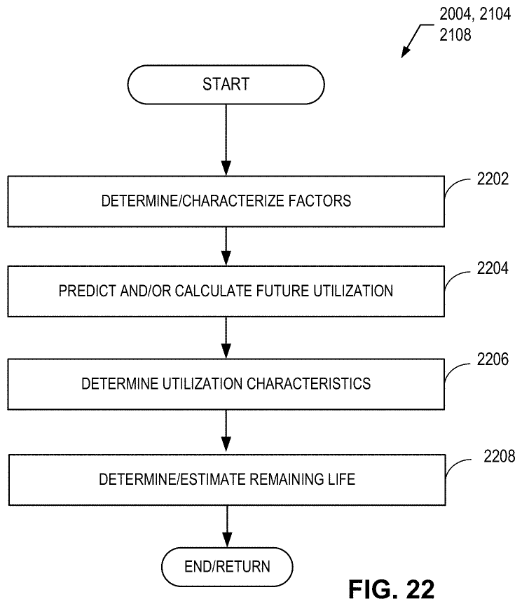

FIG. 22 is a flowchart representative of an example subroutine 2004, 2104, 2108 of FIGS. 20 and 21. The example subroutine 2004, 2104, 2108 of the illustrated example is implemented to estimate and/or predict a remaining life of at least one computing resource.

At block 2202, the example life prediction circuitry 1904 and/or the condition analyzer circuitry 1902 determines and/or characterizes factors that can affect an overall lifetime (e.g., a lifetime range, etc.) of a computing resource. For example, the overall lifetime is characterized as a function of operating temperatures and/or computations performed, etc.

At block 2204, in some examples, the condition analyzer circuitry 1902 predicts and/or calculates utilization (e.g., future utilization, forecasted utilization) of the computing resource. In some such examples, training data associated with past computational usage is utilized to train a machine learning model for predicting future utilization. In particular, the machine learning model can be developed as an LS™ model, for example, for the purposes of predicting future usage (e.g., computational usage, data bandwidth usage, etc.).

At block 2206, the condition analyzer circuitry 1902 of the illustrated example determines utilization characteristics of the computing resource. For example, the condition analyzer circuitry 1902 determines past usage and/or historical parameters.

At block 2208, the example life prediction circuitry 1904 determines and/or estimates a remaining life based on the age of the computing resource in conjunction with the predicted use/utilization, and the process ends/returns. Additionally or alternatively, the example life prediction circuitry 1904 utilizes past/historic utilization of the particular computing resource to determine and/or estimate the remaining life.

FIG. 23 is a block diagram of an example processor platform 2300 structured to execute and/or instantiate the machine readable instructions and/or the operations of FIGS. 20-22 to implement the reliability analysis system 1900 of FIG. 19. The processor platform 2300 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 2300 of the illustrated example includes processor circuitry 2312. The processor circuitry 2312 of the illustrated example is hardware. For example, the processor circuitry 2312 can be implemented by one or more integrated circuits, logic circuits, FPGAs, microprocessors, CPUs, GPUs, DSPs, and/or microcontrollers from any desired family or manufacturer. The processor circuitry 2312 may be implemented by one or more semiconductor based (e.g., silicon based) devices. In this example, the processor circuitry 2312 implements the example age monitor circuitry 1901, the example condition analyzer circuitry 1902, the example life prediction circuitry 1904, the example cooling degree analyzer circuitry 1906, the example cooling controller circuitry 1908, the example SLA manager circuitry 1910, the example telemetry data analyzer circuitry 1912 and the example service/maintenance manager circuitry 1914.

The processor circuitry 2312 of the illustrated example includes a local memory 2313 (e.g., a cache, registers, etc.). The processor circuitry 2312 of the illustrated example is in communication with a main memory including a volatile memory 2314 and a non-volatile memory 2316 by a bus 2318. The volatile memory 2314 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2316 may be implemented by flash memory and/or any other desired type of memory device. Access to the main memory 2314, 316 of the illustrated example is controlled by a memory controller 2317.

The processor platform 2300 of the illustrated example also includes interface circuitry 2320. The interface circuitry 2320 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2322 are connected to the interface circuitry 2320. The input device(s) 2322 permit(s) a user to enter data and/or commands into the processor circuitry 2312. The input device(s) 2322 can be implemented by, for example, an audio sensor, a microphone, a camera (still or video), a keyboard, a button, a mouse, a touchscreen, a track-pad, a trackball, an isopoint device, and/or a voice recognition system.

One or more output devices 2324 are also connected to the interface circuitry 2320 of the illustrated example. The output device(s) 2324 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2320 of the illustrated example, thus, typically includes a graphics driver card, a graphics driver chip, and/or graphics processor circuitry such as a GPU.

The interface circuitry 2320 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2326. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2300 of the illustrated example also includes one or more mass storage devices 2328 to store software and/or data. Examples of such mass storage devices 2328 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 2332, which may be implemented by the machine readable instructions of FIGS. 20-22, may be stored in the mass storage device 2328, in the volatile memory 2314, in the non-volatile memory 2316, and/or on a removable non-transitory computer readable storage medium such as a CD or DVD.

FIG. 24 is a block diagram of an example implementation of the processor circuitry 2312 of FIG. 23. In this example, the processor circuitry 2312 of FIG. 23 is implemented by a microprocessor 2400. For example, the microprocessor 2400 may be a general purpose microprocessor (e.g., general purpose microprocessor circuitry). The microprocessor 2400 executes some or all of the machine readable instructions of the flowcharts of FIGS. 20-22 to effectively instantiate the reliability analysis system 1900 as logic circuits to perform the operations corresponding to those machine readable instructions. In some such examples, the reliability analysis system 1900 is instantiated by the hardware circuits of the microprocessor 2400 in combination with the instructions. For example, the microprocessor 2400 may be implemented by multi-core hardware circuitry such as a CPU, a DSP, a GPU, an XPU, etc. Although it may include any number of example cores 2402 (e.g., 1 core), the microprocessor 2400 of this example is a multi-core semiconductor device including N cores. The cores 2402 of the microprocessor 2400 may operate independently or may cooperate to execute machine readable instructions. For example, machine code corresponding to a firmware program, an embedded software program, or a software program may be executed by one of the cores 2402 or may be executed by multiple ones of the cores 2402 at the same or different times. In some examples, the machine code corresponding to the firmware program, the embedded software program, or the software program is split into threads and executed in parallel by two or more of the cores 2402. The software program may correspond to a portion or all of the machine readable instructions and/or operations represented by the flowcharts of FIGS. 20-22.

The cores 2402 may communicate by a first example bus 2404. In some examples, the first bus 2404 may be implemented by a communication bus to effectuate communication associated with one(s) of the cores 2402. For example, the first bus 2404 may be implemented by at least one of an Inter-Integrated Circuit (I2C) bus, a Serial Peripheral Interface (SPI) bus, a PCI bus, or a PCIe bus. Additionally or alternatively, the first bus 2404 may be implemented by any other type of computing or electrical bus. The cores 2402 may obtain data, instructions, and/or signals from one or more external devices by example interface circuitry 2406. The cores 2402 may output data, instructions, and/or signals to the one or more external devices by the interface circuitry 2406. Although the cores 2402 of this example include example local memory 2420 (e.g., Level 1 (L1) cache that may be split into an L1 data cache and an L1 instruction cache), the microprocessor 2400 also includes example shared memory 2410 that may be shared by the cores (e.g., Level 2 (L2 cache)) for high-speed access to data and/or instructions. Data and/or instructions may be transferred (e.g., shared) by writing to and/or reading from the shared memory 2410. The local memory 2420 of each of the cores 2402 and the shared memory 2410 may be part of a hierarchy of storage devices including multiple levels of cache memory and the main memory (e.g., the main memory 2314, 2316 of FIG. 23). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2402 may be referred to as a CPU, DSP, GPU, etc., or any other type of hardware circuitry. Each core 2402 includes control unit circuitry 2414, arithmetic and logic (AL) circuitry (sometimes referred to as an ALU) 2416, a plurality of registers 2418, the local memory 2420, and a second example bus 2422. Other structures may be present. For example, each core 2402 may include vector unit circuitry, single instruction multiple data (SIMD) unit circuitry, load/store unit (LSU) circuitry, branch/jump unit circuitry, floating-point unit (FPU) circuitry, etc. The control unit circuitry 2414 includes semiconductor-based circuits structured to control (e.g., coordinate) data movement within the corresponding core 2402. The AL circuitry 2416 includes semiconductor-based circuits structured to perform one or more mathematic and/or logic operations on the data within the corresponding core 2402. The AL circuitry 2416 of some examples performs integer based operations. In other examples, the AL circuitry 2416 also performs floating point operations. In yet other examples, the AL circuitry 2416 may include first AL circuitry that performs integer based operations and second AL circuitry that performs floating point operations. In some examples, the AL circuitry 2416 may be referred to as an Arithmetic Logic Unit (ALU). The registers 2418 are semiconductor-based structures to store data and/or instructions such as results of one or more of the operations performed by the AL circuitry 2416 of the corresponding core 2402. For example, the registers 2418 may include vector register(s), SIMD register(s), general purpose register(s), flag register(s), segment register(s), machine specific register(s), instruction pointer register(s), control register(s), debug register(s), memory management register(s), machine check register(s), etc. The registers 2418 may be arranged in a bank as shown in FIG. 24. Alternatively, the registers 2418 may be organized in any other arrangement, format, or structure including distributed throughout the core 2402 to shorten access time. The second bus 2422 may be implemented by at least one of an I2C bus, a SPI bus, a PCI bus, or a PCIe bus

Each core 2402 and/or, more generally, the microprocessor 2400 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2400 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

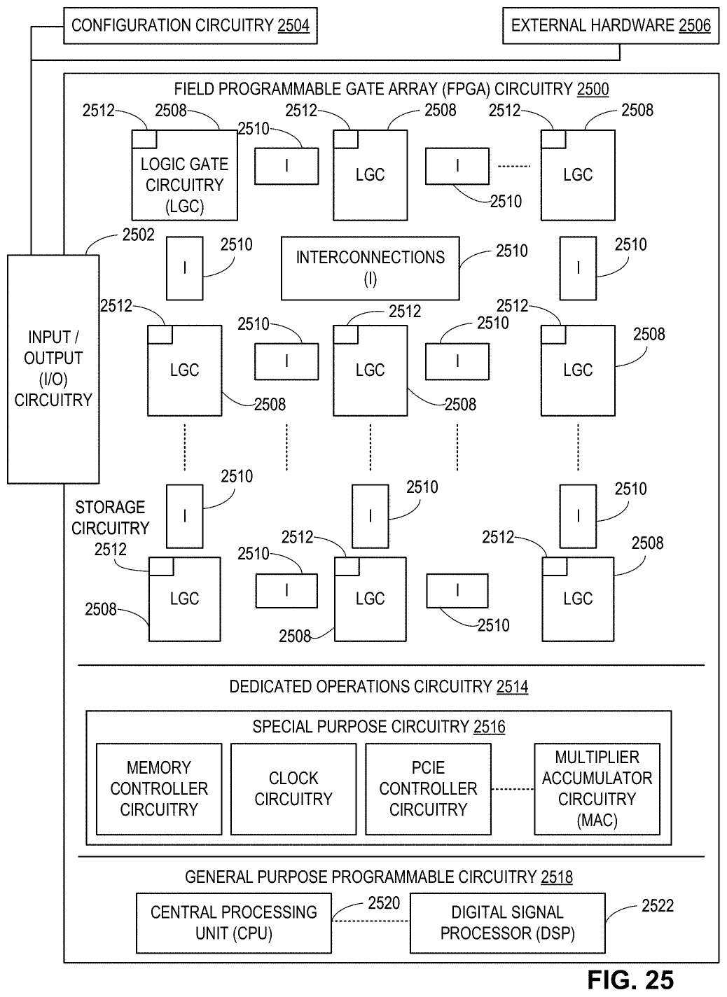

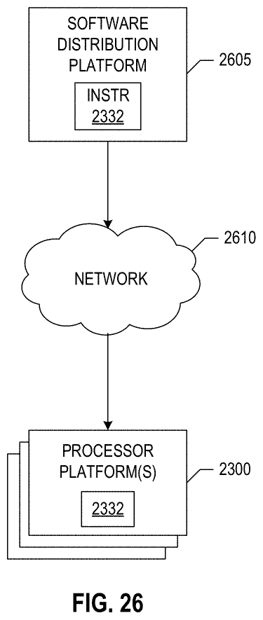

FIG. 25 is a block diagram of another example implementation of the processor circuitry 2312 of FIG. 23. In this example, the processor circuitry 2312 is implemented by FPGA circuitry 2500. For example, the FPGA circuitry 2500 may be implemented by an FPGA. The FPGA circuitry 2500 can be used, for example, to perform operations that could otherwise be performed by the example microprocessor 2400 of FIG. 24 executing corresponding machine readable instructions. However, once configured, the FPGA circuitry 2500 instantiates the machine readable instructions in hardware and, thus, can often execute the operations faster than they could be performed by a general purpose microprocessor executing the corresponding software.

More specifically, in contrast to the microprocessor 2400 of FIG. 24 described above (which is a general purpose device that may be programmed to execute some or all of the machine readable instructions represented by the flowcharts of FIGS. 20-22 but whose interconnections and logic circuitry are fixed once fabricated), the FPGA circuitry 2500 of the example of FIG. 25 includes interconnections and logic circuitry that may be configured and/or interconnected in different ways after fabrication to instantiate, for example, some or all of the machine readable instructions represented by the flowcharts of FIGS. 20-22. In particular, the FPGA circuitry 2500 may be thought of as an array of logic gates, interconnections, and switches. The switches can be programmed to change how the logic gates are interconnected by the interconnections, effectively forming one or more dedicated logic circuits (unless and until the FPGA circuitry 2500 is reprogrammed). The configured logic circuits enable the logic gates to cooperate in different ways to perform different operations on data received by input circuitry. Those operations may correspond to some or all of the software represented by the flowcharts of FIGS. 20-22. As such, the FPGA circuitry 2500 may be structured to effectively instantiate some or all of the machine readable instructions of the flowcharts of FIGS. 20-22 as dedicated logic circuits to perform the operations corresponding to those software instructions in a dedicated manner analogous to an ASIC. Therefore, the FPGA circuitry 2500 may perform the operations corresponding to the some or all of the machine readable instructions of FIGS. 20-22 faster than the general purpose microprocessor can execute the same.

In the example of FIG. 25, the FPGA circuitry 2500 is structured to be programmed (and/or reprogrammed one or more times) by an end user by a hardware description language (HDL) such as Verilog. The FPGA circuitry 2500 of FIG. 25, includes example input/output (I/O) circuitry 2502 to obtain and/or output data to/from example configuration circuitry 2504 and/or external hardware 2506. For example, the configuration circuitry 2504 may be implemented by interface circuitry that may obtain machine readable instructions to configure the FPGA circuitry 2500, or portion(s) thereof. In some such examples, the configuration circuitry 2504 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2506 may be implemented by external hardware circuitry. For example, the external hardware 2506 may be implemented by the microprocessor 2400 of FIG. 24. The FPGA circuitry 2500 also includes an array of example logic gate circuitry 2508, a plurality of example configurable interconnections 2510, and example storage circuitry 2512. The logic gate circuitry 2508 and the configurable interconnections 2510 are configurable to instantiate one or more operations that may correspond to at least some of the machine readable instructions of FIGS. 20-22 and/or other desired operations. The logic gate circuitry 2508 shown in FIG. 25 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2508 to enable configuration of the electrical structures and/or the logic gates to form circuits to perform desired operations. The logic gate circuitry 2508 may include other electrical structures such as look-up tables (LUTs), registers (e.g., flip-flops or latches), multiplexers, etc.

The configurable interconnections 2510 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2508 to program desired logic circuits.

The storage circuitry 2512 of the illustrated example is structured to store result(s) of the one or more of the operations performed by corresponding logic gates. The storage circuitry 2512 may be implemented by registers or the like. In the illustrated example, the storage circuitry 2512 is distributed amongst the logic gate circuitry 2508 to facilitate access and increase execution speed.

The example FPGA circuitry 2500 of FIG. 25 also includes example Dedicated Operations Circuitry 2514. In this example, the Dedicated Operations Circuitry 2514 includes special purpose circuitry 2516 that may be invoked to implement commonly used functions to avoid the need to program those functions in the field. Examples of such special purpose circuitry 2516 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2500 may also include example general purpose programmable circuitry 2518 such as an example CPU 2520 and/or an example DSP 2522. Other general purpose programmable circuitry 2518 may additionally or alternatively be present such as a GPU, an XPU, etc., that can be programmed to perform other operations.

Although FIGS. 24 and 25 illustrate two example implementations of the processor circuitry 2312 of FIG. 23, many other approaches are contemplated. For example, as mentioned above, modern FPGA circuitry may include an on-board CPU, such as one or more of the example CPU 2520 of FIG. 25. Therefore, the processor circuitry 2312 of FIG. 23 may additionally be implemented by combining the example microprocessor 2400 of FIG. 24 and the example FPGA circuitry 2500 of FIG. 25. In some such hybrid examples, a first portion of the machine readable instructions represented by the flowcharts of FIGS. 20-22 may be executed by one or more of the cores 2402 of FIG. 24, a second portion of the machine readable instructions represented by the flowcharts of FIGS. 20-22 may be executed by the FPGA circuitry 2500 of FIG. 25, and/or a third portion of the machine readable instructions represented by the flowcharts of FIGS. 20-22 may be executed by an ASIC. It should be understood that some or all of the reliability analysis system 1900 may, thus, be instantiated at the same or different times. Some or all of the circuitry may be instantiated, for example, in one or more threads executing concurrently and/or in series. Moreover, in some examples, some or all of the circuitry of FIG. 19 may be implemented within one or more virtual machines and/or containers executing on the microprocessor.

In some examples, the processor circuitry 2312 of FIG. 23 may be in one or more packages. For example, the microprocessor 2400 of FIG. 24 and/or the FPGA circuitry 2500 of FIG. 25 may be in one or more packages. In some examples, an XPU may be implemented by the processor circuitry 2312 of FIG. 23, which may be in one or more packages. For example, the XPU may include a CPU in one package, a DSP in another package, a GPU in yet another package, and an FPGA in still yet another package.

A block diagram illustrating an example software distribution platform 2605 to distribute software such as the example machine readable instructions 2332 of FIG. 23 to hardware devices owned and/or operated by third parties is illustrated in FIG. 1. The example software distribution platform 2605 may be implemented by any computer server, data facility, cloud service, etc., capable of storing and transmitting software to other computing devices. The third parties may be customers of the entity owning and/or operating the software distribution platform 2605. For example, the entity that owns and/or operates the software distribution platform 2605 may be a developer, a seller, and/or a licensor of software such as the example machine readable instructions 2332 of FIG. 23. The third parties may be consumers, users, retailers, OEMs, etc., who purchase and/or license the software for use and/or re-sale and/or sub-licensing. In the illustrated example, the software distribution platform 2605 includes one or more servers and one or more storage devices. The storage devices store the machine readable instructions 2332, which may correspond to the example machine readable instructions 2000, 2100 of FIGS. 20-22, as described above. The one or more servers of the example software distribution platform 2605 are in communication with an example network 2610, which may correspond to any one or more of the Internet and/or any of the example networks 116 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 2332 from the software distribution platform 2605. For example, the software, which may correspond to the example machine readable instructions 2000, 2100 of FIGS. 20-22, may be downloaded to the example processor platform 2300, which is to execute the machine readable instructions 2332 to implement the example reliability analysis system 1900. In some examples, one or more servers of the software distribution platform 2605 periodically offer, transmit, and/or force updates to the software (e.g., the example machine readable instructions 2332 of FIG. 23) to ensure improvements, patches, updates, etc., are distributed and applied to the software at the end user devices.

Example methods, apparatus, systems, and articles of manufacture to enable effective control of reliability of a computing system are disclosed herein. Further examples and combinations thereof include the following:

Example 1 includes an apparatus to manage a computing system, the apparatus comprising at least one memory, machine readable instructions, and processor circuitry to at least one of instantiate or execute the machine readable instructions to determine an effective age of a computing resource of the computing system, the computing resource associated with a degree of cooling thereof, determine a remaining life of the computing resource, compare the remaining life to a reliability threshold, and adjust at least one of a utilization or the degree of cooling of the computing resource in response to the remaining life not meeting the reliability threshold to adjust the remaining life to meet or exceed the reliability threshold.

Example 2 includes the apparatus as defined in example 1, wherein the computing resource is a first computing resource, the degree of cooling is a first degree of cooling and the remaining life is a first remaining life, the effective age is a first effective age, and wherein the processor circuitry is to at least one of instantiate or execute the machine readable instructions to determine a second effective age of a second computing resource of the computing system, the second computing resource associated with a second degree of cooling, determine a second remaining life of the second computing resource, compare the first remaining life to the second remaining life, and cause reduction of at least one of the first or second degrees of cooling and an increase of the other of the first or second degrees of cooling based on the comparison of the first remaining life to the second remaining life.

Example 3 includes the apparatus as defined in example 2, wherein the degree to which the at least one of the first or second degrees of cooling is reduced is determined based on substantially equating the first remaining life to the second remaining life.

Example 4 includes the apparatus as defined in any of examples 1 to 3, wherein the processor circuitry is to execute the instructions to adjust the degree of cooling by controlling at least one valve in a fluid cooling system.

Example 5 includes the apparatus as defined in any of examples 1 to 4, wherein the processor circuitry is to execute the instructions to control the utilization of the computing resource.

Example 6 includes the apparatus as defined in example 5, wherein the processor circuitry is to execute the instructions to control the utilization based on at least one of a service level agreement (SLA) or a performance requirement.

Example 7 includes the apparatus as defined in any of examples 5 or 6, wherein the processor circuitry is to execute the instructions to control the utilization by rescheduling or redistributing workloads for execution by the computing resource.

Example 8 includes the apparatus as defined in any of examples 1 to 7, wherein the processor circuitry is to execute the instructions to calculate the adjusted degree of cooling.

Example 9 includes the apparatus as defined in any of examples 1 to 8, wherein the processor circuitry is to execute the instructions to determine the remaining life based on predicted usage of the computing resource.

Example 10 includes a non-transitory machine readable medium comprising instructions, which when executed, cause processor circuitry to determine an effective age of a computing resource of a computing system, the computing resource associated with a degree of cooling thereof, determine a remaining life of the computing resource, compare the remaining life to a reliability threshold, and adjust at least one of the degree of cooling or a utilization of the computing resource in response to the remaining life not meeting the reliability threshold to adjust the remaining life to meet or exceed the reliability threshold.

Example 11 includes the non-transitory machine readable medium as defined in example 10, wherein the computing resource is a first computing resource, the degree of cooling is a first degree of cooling and the remaining life is a first remaining life, the effective age is a first effective age, and wherein the instructions cause the processor circuitry to determine an effective age of a second computing resource of the computing system, the second computing resource associated with a second degree of cooling, determine a second remaining life of the second computing resource, compare the first remaining life to the second remaining life, and cause reduction of at least one of the first or second degrees of cooling and an increase of the other of the first or second degrees of cooling based on the comparison of the first remaining life to the second remaining life.

Example 12 includes the non-transitory machine readable medium as defined in example 11, wherein the instructions cause the processor circuitry to calculate a degree to which the at least one of the first or second degrees of cooling is reduced.

Example 13 includes the non-transitory machine readable medium as defined in any of examples 11 or 12, wherein the degree to which the at least one of the first or second degrees of cooling is reduced is determined based on substantially equating the first remaining life to the second remaining life.

Example 14 includes the non-transitory machine readable medium as defined in any of examples 10 to 13, wherein the instructions cause the processor circuitry to adjust the degree of cooling by controlling at least one valve in a fluid cooling system.

Example 15 includes the non-transitory machine readable medium as defined in any of examples 10 to 14, wherein the processor circuitry is to execute the instructions to control the utilization of the computing resource.

Example 16 includes the non-transitory machine readable medium as defined in example 15, wherein the utilization is controlled based on at least one of a service level agreement (SLA) or a performance requirement.

Example 17 includes the non-transitory machine readable medium as defined in any of examples 15 or 16, wherein the utilization is controlled by rescheduling or redistributing workloads for execution by the computing resource.

Example 18 includes the non-transitory machine readable medium as defined in any of examples 10 to 17, wherein the instructions cause the processor circuitry to calculate the adjusted degree of cooling.

Example 19 includes the non-transitory machine readable medium as defined in any of examples 10 to 18, wherein the instructions cause the processor circuitry to determine the remaining life based on predicted usage of the computing resource.

Example 20 includes a method comprising determining, by executing instructions with processor circuitry, an effective age of a computing resource of a computing system, the computing resource associated with a degree of cooling thereof, determining, by executing instructions with the processor circuitry, a remaining life of the computing resource, comparing, by executing instructions with the processor circuitry, the remaining life to a reliability threshold, and adjusting, by executing instructions with the processor circuitry, at least one of the degree of cooling or a utilization of the computing resource in response to the remaining life not meeting the reliability threshold to adjust the remaining life to meet or exceed the reliability threshold.

Example 21 includes the method as defined in example 20, wherein the computing resource is a first computing resource, the degree of cooling is a first degree of cooling and the remaining life is a first remaining life, the effective age is a first effective age, and further including determining, by executing instructions with the processor circuitry, a second effective age of a second computing resource of the computing system, the second computing resource associated with a second degree of cooling, determining, by executing instructions with the processor circuitry, a second remaining life of the second computing resource, comparing, by executing instructions with the processor circuitry, the first remaining life to the second remaining life, and causing, by executing instructions with the processor circuitry, reduction of at least one of the first or second degrees of cooling and an increase of the other of the first or second degrees of cooling based on the comparison of the first remaining life to the second remaining life.

Example 22 includes the method as defined in example 21, further including calculating, by executing instructions with the processor circuitry, a degree to which the at least one of the first or second degrees of cooling is reduced.

Example 23 includes the method as defined in any of examples 21 or 22, wherein the degree to which the at least one of the first or second degrees of cooling is reduced is determined based on substantially equating the first remaining life to the second remaining life.

Example 24 includes the method as defined in any of examples 20 to 23, wherein the adjusting the degree of cooling includes controlling at least one valve in a fluid cooling system.

Example 25 includes the method as defined in any of examples 20 to 24, wherein the utilization of the computing resource is to be controlled to adjust the remaining life.

Example 26 includes the method as defined in example 25, wherein the utilization is controlled based on at least one of a service level agreement (SLA) or a performance requirement.

Example 27 includes the method as defined in any of examples 25 or 26, wherein the utilization is controlled by rescheduling or redistributing workloads for execution by the computing resource.

Example 28 includes the method as defined in any examples 20 to 27, further including calculating, by executing instructions with the processor circuitry, the adjusted degree of cooling.

Example 29 includes an apparatus to manage a computing system, the apparatus comprising means for determining an effective age of a computing resource of the computing system, the computing resource associated with a degree of cooling thereof, means for determining a remaining life of the computing resource, means for comparing the remaining life to a reliability threshold, and means for adjusting at least one of a utilization or the degree of cooling of the computing resource in response to the remaining life not meeting the reliability threshold to adjust the remaining life to meet or exceed the reliability threshold.

Example 30 includes the apparatus as defined in example 29, wherein the means for adjusting at least one of a utilization or the degree of cooling of the computing resource includes means for controlling at least one valve in a fluid cooling system.

Example 31 includes the apparatus as defined in any of examples 29 or 30, further including means for determining the adjusted degree of cooling.

From the foregoing, it will be appreciated that example systems, methods, apparatus, and articles of manufacture have been disclosed that enable increased reliability of overall computing and/or network systems. Examples disclosed herein can monitor and control cooling, as well as workloads of computing resources to ensure that an overall system meets reliability standards and/or survivability goals. Disclosed systems, methods, apparatus, and articles of manufacture improve the efficiency of a computing device by enabling a more reliable operation thereof and, thus, avoiding operation with compromised and/or failed components/devices that can cause significant downtime, and enabling stressed/aged components to be operated with reduced workloads. Disclosed systems, methods, apparatus, and articles of manufacture are accordingly directed to one or more improvement(s) in the operation of a machine such as a computer or other electronic and/or mechanical device.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus to manage a computing system, the apparatus comprising:
at least one memory;
machine readable instructions; and
processor circuitry to at least one of instantiate or execute the machine readable instructions to:
determine an effective age of a computing resource of the computing system, the computing resource associated with a degree of cooling thereof,
determine a remaining life of the computing resource,
compare the remaining life to a reliability threshold, and
adjust at least one of a utilization or the degree of cooling of the computing resource in response to the remaining life not meeting the reliability threshold to adjust the remaining life to meet or exceed the reliability threshold.

2. The apparatus as defined in claim 1, wherein the computing resource is a first computing resource, the degree of cooling is a first degree of cooling and the remaining life is a first remaining life, the effective age is a first effective age, and wherein the processor circuitry is to at least one of instantiate or execute the machine readable instructions to:
determine a second effective age of a second computing resource of the computing system, the second computing resource associated with a second degree of cooling;
determine a second remaining life of the second computing resource;
compare the first remaining life to the second remaining life; and
cause reduction of at least one of the first or second degrees of cooling and an increase of the other of the first or second degrees of cooling based on the comparison of the first remaining life to the second remaining life.

3. The apparatus as defined in claim 2, wherein the degree to which the at least one of the first or second degrees of cooling is reduced is determined based on substantially equating the first remaining life to the second remaining life.

4. The apparatus as defined in claim 1, wherein the processor circuitry is to execute the instructions to adjust the degree of cooling by controlling at least one valve in a fluid cooling system.

5. The apparatus as defined in claim 1, wherein the processor circuitry is to execute the instructions to control the utilization of the computing resource.

6. The apparatus as defined in claim 5, wherein the processor circuitry is to execute the instructions to control the utilization based on at least one of a service level agreement (SLA) or a performance requirement.

7. The apparatus as defined in claim 5, wherein the processor circuitry is to execute the instructions to control the utilization by rescheduling or redistributing workloads for execution by the computing resource.

8. The apparatus as defined in claim 1, wherein the processor circuitry is to execute the instructions to calculate the adjusted degree of cooling.

9. The apparatus as defined in claim 1, wherein the processor circuitry is to execute the instructions to determine the remaining life based on predicted usage of the computing resource.

10. A non-transitory machine readable medium comprising instructions, which when executed, cause processor circuitry to:
determine an effective age of a computing resource of a computing system, the computing resource associated with a degree of cooling thereof;
determine a remaining life of the computing resource;
compare the remaining life to a reliability threshold; and
adjust at least one of the degree of cooling or a utilization of the computing resource in response to the remaining life not meeting the reliability threshold to adjust the remaining life to meet or exceed the reliability threshold.

11. The non-transitory machine readable medium as defined in claim 10, wherein the computing resource is a first computing resource, the degree of cooling is a first degree of cooling and the remaining life is a first remaining life, the effective age is a first effective age, and wherein the instructions cause the processor circuitry to
determine an effective age of a second computing resource of the computing system, the second computing resource associated with a second degree of cooling;
determine a second remaining life of the second computing resource;
compare the first remaining life to the second remaining life; and
cause reduction of at least one of the first or second degrees of cooling and an increase of the other of the first or second degrees of cooling based on the comparison of the first remaining life to the second remaining life.

12. The non-transitory machine readable medium as defined in claim 11, wherein the instructions cause the processor circuitry to calculate a degree to which the at least one of the first or second degrees of cooling is reduced.

13. The non-transitory machine readable medium as defined in claim 11, wherein the degree to which the at least one of the first or second degrees of cooling is reduced is determined based on substantially equating the first remaining life to the second remaining life.

14. The non-transitory machine readable medium as defined in claim 10, wherein the instructions cause the processor circuitry to adjust the degree of cooling by controlling at least one valve in a fluid cooling system.

15. The non-transitory machine readable medium as defined in claim 10, wherein the processor circuitry is to execute the instructions to control the utilization of the computing resource.

16. The non-transitory machine readable medium as defined in claim 15, wherein the utilization is controlled based on at least one of a service level agreement (SLA) or a performance requirement.

17. The non-transitory machine readable medium as defined in claim 15, wherein the utilization is controlled by rescheduling or redistributing workloads for execution by the computing resource.

18. The non-transitory machine readable medium as defined in claim 10, wherein the instructions cause the processor circuitry to calculate the adjusted degree of cooling.

19. The non-transitory machine readable medium as defined in claim 10, wherein the instructions cause the processor circuitry to determine the remaining life based on predicted usage of the computing resource.

20. A method comprising:
determining, by executing instructions with processor circuitry, an effective age of a computing resource of a computing system, the computing resource associated with a degree of cooling thereof,
determining, by executing instructions with the processor circuitry, a remaining life of the computing resource,
comparing, by executing instructions with the processor circuitry, the remaining life to a reliability threshold, and
adjusting, by executing instructions with the processor circuitry, at least one of the degree of cooling or a utilization of the computing resource in response to the remaining life not meeting the reliability threshold to adjust the remaining life to meet or exceed the reliability threshold.

21. The method as defined in claim 20, wherein the computing resource is a first computing resource, the degree of cooling is a first degree of cooling and the remaining life is a first remaining life, the effective age is a first effective age, and further including:
determining, by executing instructions with the processor circuitry, a second effective age of a second computing resource of the computing system, the second computing resource associated with a second degree of cooling;
determining, by executing instructions with the processor circuitry, a second remaining life of the second computing resource;
comparing, by executing instructions with the processor circuitry, the first remaining life to the second remaining life; and
causing, by executing instructions with the processor circuitry, reduction of at least one of the first or second degrees of cooling and an increase of the other of the first or second degrees of cooling based on the comparison of the first remaining life to the second remaining life.

22. The method as defined in claim 21, further including calculating, by executing instructions with the processor circuitry, a degree to which the at least one of the first or second degrees of cooling is reduced.

23. The method as defined in claim 21, wherein the degree to which the at least one of the first or second degrees of cooling is reduced is determined based on substantially equating the first remaining life to the second remaining life.

24. The method as defined in claim 20, wherein the adjusting the degree of cooling includes controlling at least one valve in a fluid cooling system.

25. The method as defined in claim 20, wherein the utilization of the computing resource is to be controlled to adjust the remaining life.

26. The method as defined in claim 25, wherein the utilization is controlled based on at least one of a service level agreement (SLA) or a performance requirement.

27. The method as defined in claim 25, wherein the utilization is controlled by rescheduling or redistributing workloads for execution by the computing resource.

28. The method as defined in claim 20, further including calculating, by executing instructions with the processor circuitry, the adjusted degree of cooling.

29. (canceled)

30. (canceled)

31. (canceled)
